(19) United States
(12) Patent Application Publication
(10) Pub. No.: US 2026/0173965 A1
(43) Pub. Date: Jun. 18, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Yonghyun Kim, Suwon-si (KR); Wonil Seo, Suwon-si (KR); Taejun Jeon, Suwon-si (KR)

(21) Appl. No.: 19/281,821

(22) Filed: Jul. 28, 2025

(30) Foreign Application Priority Data
Dec. 12, 2024 (KR) 10-2024-0185077

(51) Int. Cl. H01L 23/00; H01L 23/29; H01L 23/31; H01L 23/538; H01L 25/00; H01L 25/065; H01L 25/18; H10B 80/00; H10D 80/30

(52) U.S. Cl. CPC H10W 90/00; H10W 70/611; H10W 74/117; H10W 74/121; H10W 74/47; H10W 74/473; H10W 90/401; H10B 80/00; H10D 80/30; H10W 72/07352; H10W 72/07353; H10W 72/321; H10W 72/331; H10W 72/334; H10W 72/354; H10W 72/634; H10W 72/683; H10W 72/868; H10W 72/877; H10W 72/886; H10W 72/9415; H10W 72/9445; H10W 74/15; H10W 90/20; H10W 90/24; H10W 90/724; H10W 90/732; H10W 90/734; H10W 90/752; H10W 90/754; H10W 90/762; H10W 90/764

(57) ABSTRACT

A semiconductor package and a method of manufacturing the same are provided such that the total thickness of a package and the pitch of a chip pad are decreased thereby reducing cracks in wiring. The semiconductor package includes a package substrate, at least two semiconductor chips stacked on the package substrate, in a stepped structure, a side insulation layer disposed on one side surface of each of the at least two semiconductor chips, and a conductive connection pattern disposed on a slope surface of the side insulation layer, a portion of an upper surface of each of the at least two semiconductor chips, and a portion of an upper surface of the package substrate, the conductive connection pattern connecting the at least two semiconductor chips to the package substrate, wherein the conductive connection pattern includes a straight line portion and a bent line portion.

### CROSS-REFERENCE TO RELATED APPLICATION

This application is based on and claims priority under 35 U.S.C. § 119 to Korean Patent Application No. 10-2024-0185077, filed on Dec. 12, 2024, in the Korean Intellectual Property Office, the disclosure of which is incorporated by reference herein in its entirety.

### BACKGROUND

The inventive concept relates to a semiconductor package, and more particularly, to a semiconductor package including a chip stack structure and a method of manufacturing the semiconductor package.

In accordance with the rapid development of the electronics industry and the increasing demands of users, electronic devices are being miniaturized further and becoming more multifunctional. As electronic devices are miniaturized and made more lightweight, semiconductor packages are also being miniaturized and made more lightweight, and moreover, semiconductor packages are required to have high performance, large capacity, and high reliability. Recently, in order to implement large capacity and high performance, the thicknesses of semiconductor packages are increasing, and power supplied thereto is increasing. However, an increase in thickness may conflict with miniaturization and weight reduction, and an increase in supplied power may adversely affect high reliability.

### SUMMARY

The inventive concept provides a semiconductor package and a method of manufacturing the same, which may decrease a total thickness of a package and a pitch of a chip pad and may prevent a crack of a wiring.

The object of the inventive concept is not limited to the aforesaid, but other objects not described herein will be clearly understood by those of ordinary skill in the art from descriptions below.

A semiconductor package according to an embodiment includes a package substrate, first and second semiconductor chips stacked on the package substrate in a stepped configuration. The first semiconductor chip of the first and second semiconductor chips has a first side surface and the second semiconductor chip of the first and second semiconductor chips has a second side surface. The semiconductor package further includes a first side insulation layer disposed on the first and second side surfaces of the first and second semiconductor chips and a first conductive connection pattern. The first side insulation layer has a first slope surface. The first conductive connection pattern electrically connects the first and second semiconductor chips to the package substrate. The first conductive connection pattern is in contact with the first slope surface of the first side insulation layer. The first conductive connection pattern is disposed on the first and second semiconductor chips. The first conductive connection pattern is disposed on the package substrate. The first conductive connection pattern comprises a first portion formed of a first conductive material, and a second portion formed of a second conductive material different from the first conductive material. The first and second portions are directly electrically connected to each other in series, and an electrical conductivity of the first portion is greater than an electrical conductivity of the second portion.

A semiconductor package according to an embodiment includes a package substrate, first and second semiconductor chips stacked on the package substrate in a stepped structure, a first side insulation layer, the first side insulation layer having a first slope surface and a first conductive connection pattern. The first semiconductor chip of the first and second semiconductor chips has a first side surface and the second semiconductor chip of the first and second semiconductor chips has a second side surface. The first side insulation layer is disposed on the first and second side surfaces of the first and second semiconductor chips. The first conductive connection pattern electrically connects the first and second semiconductor chips to the package substrate. The first conductive connection pattern is in contact with the first slope surface of the first side insulation layer. The first conductive connection pattern is disposed on a portion of each of upper surfaces of the first and second semiconductor chips. The first conductive connection pattern is disposed on a portion of an upper surface of the package substrate. The semiconductor package further includes a sealant sealing the first and second semiconductor chips, on the package substrate. The first side insulation layer has first and second insulation patterns. The first insulation pattern is in contact with the first side surface of the first semiconductor chip configured to have a first triangular pillar shape. In a cross sectional view, the first triangular pillar shape has a first right-angled triangular shape. The second insulation pattern is in contact with the second side surface of the second semiconductor chip configured to have a second triangular pillar shape. In a cross sectional view, the second triangular pillar shape has a second right-angled triangular shape. In the cross sectional view, each of the first and second right-angled triangular shapes have two adjacent line segments and a hypotenuse segment extending between the two adjacent line segments. The two adjacent line segments are perpendicular to each other, and the hypotenuse segment is at an acute angle to the upper surface of the package substrate. The first and second semiconductor chips and the first and second insulation patterns are arranged such than each of the first and second side surfaces is configured to be in contact with one of a corresponding two of the adjacent line segments. The first slope surface of the first side insulation layer includes first and second sub-surfaces each of which is configured to corresponds to one of the hypotenuse segments of the first and second right-angled triangular shapes, the first conductive connection pattern comprises a first portion and a second portion, the first portion has a linear shape and is in contact with the first slope surface of the first side insulation layer, and the first and second portions are directly electrically connected to each other in series. The second portion has a bent shape. The second portion is in contact with the first sub-surface of the first slope surface of the first side insulation layer and the first semiconductor chip or the second sub-surface of the first slope surface of the first side insulation layer and the package substrate.

A semiconductor package according to an embodiment includes a package substrate, first and second semiconductor chips stacked on the package substrate in a stepped configuration, a side insulation layer disposed on a side surface of each of the first and second semiconductor chips, and a conductive connection pattern in contact with the side insulation layer and connecting the first and second semiconductor chips to the package substrate, wherein the conductive connection pattern includes a first conductive material portion and a second conductive material portion, the first conductive material portion is higher in electrical conductivity than the second conductive material portion, and the second conductive material portion is higher in flexibility than the first conductive material portion.

A method of manufacturing a semiconductor package, according to an embodiment, includes stacking first and second semiconductor chips on a package substrate in a stepped configuration, forming a side insulation layer on a side surface of each of the first and second semiconductor chips, forming a conductive connection pattern on a slope surface of the side insulation layer, an upper surface of each of the first and second semiconductor chips, and an upper surface of the package substrate. The method further includes forming a sealant to seal the first and second semiconductor chips, on the package substrate. The conductive connection pattern connecting the first and second semiconductor chips to the package substrate. The conductive connection pattern comprises a straight line portion formed of a first conductive material and a bent line portion formed of a second conductive material which is different from the first conductive material. The forming of the conductive connection pattern comprises forming one of the straight line portion and the bent line portion in a first process step and forming the other of the straight line portion and the bent line portion in a second process step.

In the method of manufacturing a semiconductor package according to an embodiment, the side insulation layer includes a side insulation pattern configured to have a triangular pillar shape. In a cross sectional view, the triangular pillar shape has a right-angled triangular shape. The side surface of the first semiconductor chip is in contact with a side surface of the side insulation layer, the side surface of the side insulation layer is configured to correspond to a height of the right-angled triangular shape, and the slope surface of the side insulation layer is configured to correspond to a hypotenuse segment of the right-angled triangular shape and extends from an upper end of the side surface of the first semiconductor chip. The hypotenuse segment has an acute angle to the upper surface of the package substrate, and the straight line portion is formed on the slope surface of the side insulation layer. The bent line portion is formed at a portion of the slope surface of the side insulation layer, a portion of an upper surface of the first semiconductor chip, a portion of the slope surface of the side insulation layer, and a portion of the upper surface of the package substrate.

In the method of manufacturing a semiconductor package according to an embodiment, the side insulation layer comprises an extension portion covering the upper surface of the first semiconductor chip from a chip pad of the first semiconductor chip up to the side surface of the first semiconductor chip, and the bent line portion is formed on the slope surface of the side insulation layer and the extension portion.

In the method of manufacturing a semiconductor package according to an embodiment, the straight line portion is formed of the first conductive material having greater electrical conductivity than the bent line portion, and the bent line portion is formed of the second conductive material having greater flexibility than the straight line portion.

In the method of manufacturing a semiconductor package according to an embodiment, the forming of the conductive connection pattern comprises forming one of the straight line portion and the bent line portion, and subsequently forming the other. The bent line portion connects the straight line portion to a chip pad of the first semiconductor chip or a substrate pad of the package substrate.

### BRIEF DESCRIPTION OF THE DRAWINGS

Embodiments will be more clearly understood from the following detailed description taken in conjunction with the accompanying drawings in which:

FIGS. 1A and 1B are a cross-sectional view and a plan view of a semiconductor package according to an embodiment;

FIGS. 2A and 2B are an enlarged cross-sectional view of a region A of FIG. 1A and an enlarged plan view of a region B of FIG. 1B;

FIG. 3 is a simulation image showing stress adjacent to a side surface of a semiconductor chip;

FIG. 4 is a plan view of a semiconductor package according to an embodiment;

FIGS. 5, 6A and 6B are cross-sectional views of a semiconductor package according to embodiments;

FIGS. 7A to 7C are a cross-sectional view, a plan view, and an enlarged cross-sectional view of a semiconductor package according to an embodiment;

FIGS. 8A to 8E are cross-sectional views illustrating a process of a method of manufacturing a semiconductor package, according to an embodiment;

FIGS. 9A and 9B are cross-sectional views illustrating a process of a method of manufacturing a semiconductor package, according to an embodiment;

FIGS. 10A to 10D are cross-sectional views illustrating a process of a method of manufacturing a semiconductor package, according to an embodiment; and

FIGS. 11A to 11C are cross-sectional views illustrating a process of a method of manufacturing a semiconductor package, according to an embodiment.

### DETAILED DESCRIPTION OF THE EMBODIMENTS

Hereinafter, embodiments will be described in detail with reference to the accompanying drawings. Like reference numerals refer to like elements throughout the drawings and specification, and duplicated descriptions may be omitted.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “linear”, “perpendicular,” “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality.

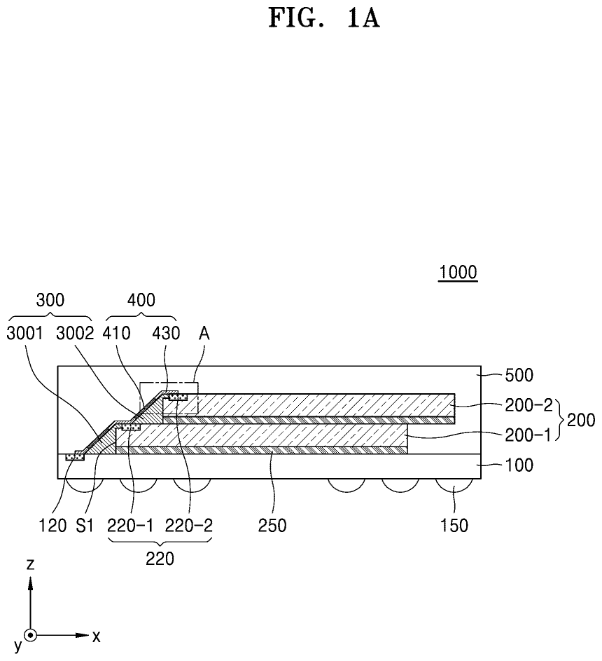

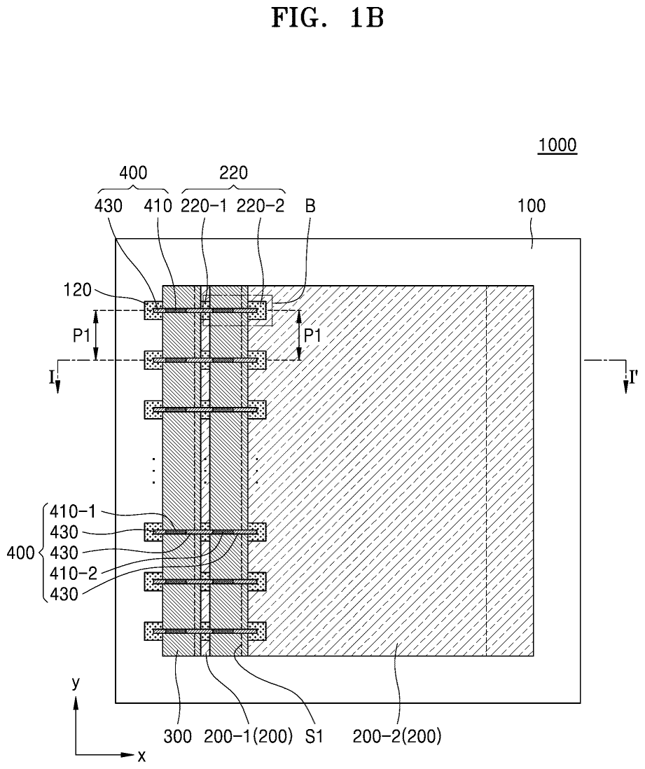

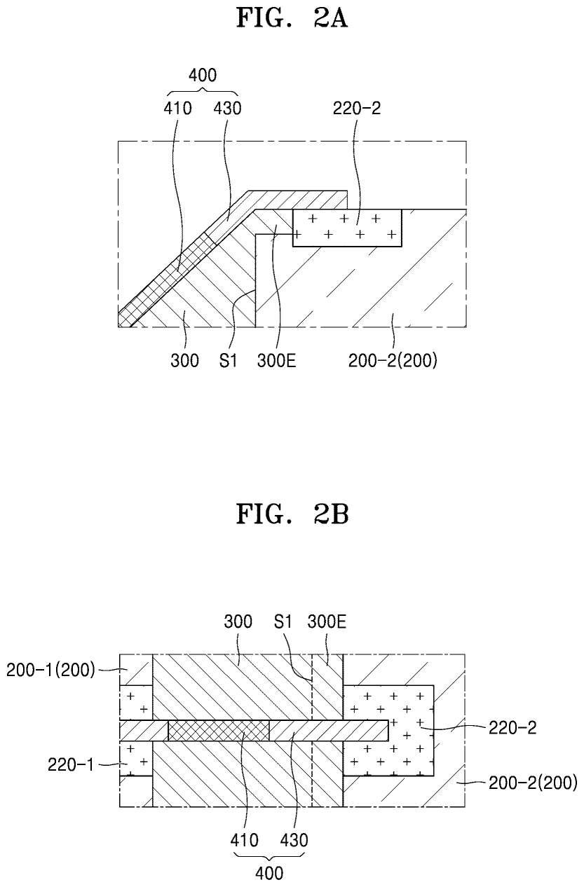

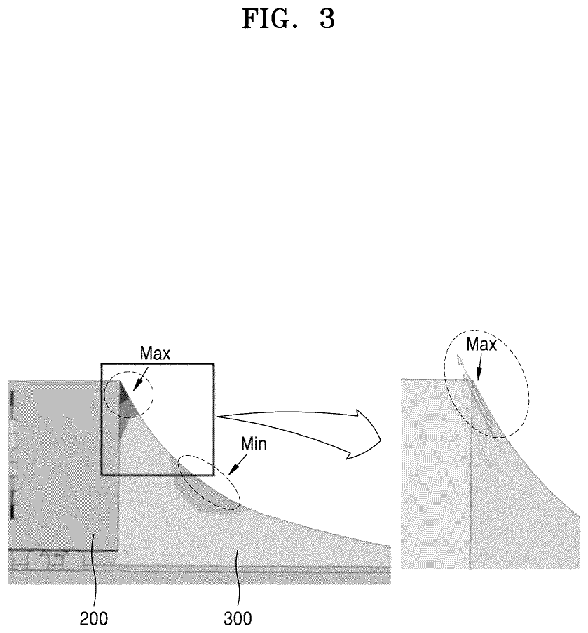

FIGS. 1A and 1B are a cross-sectional view and a plan view of a semiconductor package according to an embodiment, and FIG. 1A is a cross-sectional view taken along line I-I′ of FIG. 1B. FIG. 2A is an enlarged cross-sectional view of a region A of FIG. 1A, and FIG. 2B is an enlarged plan view of a region B of FIG. 1B. FIG. 3 is a simulation photograph (image) showing stress contour in a side insulation layer with respect to a side surface of a semiconductor chip.

Referring to FIGS. 1A to 3, a semiconductor package 1000 according to an embodiment may include a package substrate 100, a semiconductor chip 200, a side insulation layer 300, a conductive connection pattern 400, and a sealant 500.

The package substrate 100 may include a substrate body layer, a substrate protection layer, a substrate pad 120, and an external pad. An external connection terminal 150 may be disposed on the external pad. For convenience of illustration, in the figures including FIG. 1A, the substrate body layer and the substrate protection layer may be illustrated as a single layer without distinction, and the external pad may not be illustrated.

The substrate body layer may include various materials. For example, the substrate body layer may include silicon, ceramic, an organic material, glass, or epoxy resin, based on (depending on) the kind of package substrate. In the semiconductor package 1000 according to an embodiment, the package substrate 100 may be a printed circuit board (PCB), and the substrate body layer may be based on (formed of) epoxy resin (or flame retardant 4 (FR-4)), phenol resin, or bismaleimide triazine (BT). However, the material of the substrate body layer is not limited to the materials described above.

The substrate body layer may be formed of a single layer or a multilayer. For example, the package substrate 100 may be a single-layer PCB where a wiring is formed in only one surface or a double-layer PCB where wirings are formed in both surfaces. In the double-layer PCB, an upper wiring and a lower wiring may be electrically connected to each other through a via contact passing through the substrate body layer. In an example, a three or more-layer copper (Cu) foil may be formed in the substrate body layer by using an insulator which is a prepreg. A three or more layer wiring may be formed in the substrate body layer, based on (depending on) the number of layers of the Cu foil.

The substrate protection layer may be disposed on a lower surface and an upper surface of the substrate body layer. The substrate protection layer may cover and protect wirings disposed on the lower surface and the upper surface of the substrate body layer. The substrate protection layer may include, for example, solder resist (SR). However, the material of the substrate protection layer is not limited to SR. For example, the substrate protection layer may include an insulation layer including various materials, based on the kind or function of the substrate body layer. The substrate pad 120 on the upper surface of the substrate body layer and the external pad on the lower surface of the substrate body layer may be exposed from the substrate protection layer. Furthermore, the substrate body layer may occupy the majority of the package substrate 100, thereby having a volume substantially the same as that of the package substrate 100 in appearance. Hereinafter, therefore, the terms ‘substrate body layer’ and ‘package substrate’ may be used interchangeably.

The substrate pad 120 may be disposed on the upper surface of the package substrate 100 and may be electrically connected to a chip pad 220 of the semiconductor chip 200 through the conductive connection pattern 400. In detail, a first chip pad 220-1 of a first semiconductor chip 200-1 may be directly electrically connected to the substrate pad 120 through the conductive connection pattern 400, and moreover, a second chip pad 220-2 of a second semiconductor chip 200-2 may be directly electrically connected to the substrate pad 120 through the conductive connection pattern 400. The second chip pad 220-2 may be directly electrically connected to the substrate pad 120 via the first chip pad 220-1. Therefore, the number of substrate pads 120 may be equal to the number of chip pads 220 of each of the first and second semiconductor chips 200-1 and 200-2.

The first and second semiconductor chips 200-1 and 200-2 may be vertically stacked in a stepped configuration, such that each successive chip is offset laterally from the chip beneath it, forming a staircase-like structure. This stepped arrangement facilitates easier routing of interconnects, improved signal integrity, and better thermal dissipation, as the first and second chip pads 220-1 and 220-2 are exposed and accessible along the stepped edges.

The substrate pad 120 may be disposed on the upper surface of the package substrate 100, based on (considering) a direction in which stepped configuration (or stepped structure) of the semiconductor chip 200 is formed. For example, as seen in FIG. 1B, in the stepped structure of the semiconductor chips 200 may be formed to be offset in an x direction, and the substrate pad 120 may be disposed on the upper surface of the package substrate 100 on the left of the semiconductor chip 200 such that each of the substrate pads 120 is disposed adjacent to a pair of one the first chip pads 220-1 and on second chip pads 220-2 in the x direction. The substrate pads 120 may be disposed on the upper surface of the package substrate 100 in a row in a y direction and may be disposed to have a first pitch P1 in the y direction.

The external pad may be disposed on the lower surface of the package substrate 100. As described above, the substrate protection layer may be disposed on the lower surface of the package substrate 100, and the external pad may pass through the substrate protection layer and may be exposed to the outside. The external pad may be connected to an internal wiring of the substrate body layer through a via contact. The external connection terminal 150 may be disposed on the external pad.

The first and second semiconductor chips 200-1 and 200-2 may be mounted on the package substrate 100. The semiconductor chips 200 may include, for example, the first semiconductor chip 200-1 and the second semiconductor chip 200-2. The semiconductor package 1000 according to an embodiment may include two semiconductor chips 200-1 and 200-2, but the number of semiconductor chips 200 is not limited to two. For example, the semiconductor package 1000 according to an embodiment may include one semiconductor chip 200 or three or more semiconductor chips 200.

The first semiconductor chip 200-1 and the second semiconductor chip 200-2 may be sequentially stacked in a stepped structure on the package substrate 100. Two semiconductor chips 200-1 and 200-2 may be substantially equal to each other in size, structure, function. Hereinafter, therefore, the first semiconductor chip 200-1 will be mainly described.

The first semiconductor chip 200-1 may include a first chip body layer, a first chip protection layer, and a first chip pad 220-1. The first chip body layer may include a semiconductor substrate, an integrated device layer and a multi-wiring layer. The semiconductor substrate may be formed of a semiconductor material and/or a silicon wafer. The integrated device layer may be formed on the semiconductor substrate and may include various kinds of elements. For example, the integrated device layer may include various active elements and/or passive elements such as transistors, which act as fundamental components in functional units or devices like memory devices, logic devices, system large scale integration (LSI), a complementary metal oxide semiconductor (CMOS) imaging sensor (CIS), and a micro-electro-mechanical system (MEMS). In an embodiment, each of the first and second semiconductor chips 220-1 and 220-2 may be a memory chip. In another embodiment, the first semiconductor chip 220-1 may be a logic chip and the second semiconductor chip 220-2 may be a memory chip.

The transistor may be, for example, a bipolar junction transistor (BJT) or a field effect transistor (FET) such as a planar FET or a FinFET. The memory devices may include, for example, a volatile memory device such as dynamic random access memory (DRAM) or static random access memory (SRAM) or a non-volatile memory device such as flash memory, electrically erasable programmable read-only memory (EEPROM), phase-change random access memory (PRAM), magnetoresistive random access memory (MRAM), ferroelectric random access memory (FeRAM), or resistive random access memory (RRAM).

The logic devices may include, for example, circuits such as an AND gate, a NAND gate, an OR gate, a NOR gate, an exclusive OR (XOR) gate, an exclusive NOR (XNOR) gate, an inverter (INV), an adder (ADD), a delay (DLY), a filter (FIL), a multiplexer (MXT/MXIT), an OR/AND/INVERTER (AOI), an AND/OR/INVERTER (AOI), an AND/OR/INVERTER (AOI), a D flip-flop, a reset flip-flop, a master-slave flip-flop, a latch, a counter, or a buffer. The logic devices may perform various signal processing such as analog signal processing, analog-to-digital (A/D) conversion, and control.

For example, in the semiconductor package 1000 according to an embodiment, the first semiconductor chip 200-1 may be a DRAM chip including DRAM cells in the integrated device layer. However, in the semiconductor package 1000 according to an embodiment, the kind of first semiconductor chip 200-1 is not limited to the DRAM chip.

The first chip protection layer may cover and protect an upper surface of the first chip body layer. The first chip protection layer may include, for example, an insulation layer such as an oxide layer or a nitride layer. However, a material of the first chip protection layer is not limited to the materials described above.

The first chip pad 200-1 may be disposed on an upper surface of the first semiconductor chip 200-1. Therefore, the upper surface of the first semiconductor chip 200-1 may be an active surface, and a lower surface of the first semiconductor chip 200-1 may be an inactive surface. The first chip pads 220-1 may be disposed close to one portion (e.g., edge) of the first semiconductor chip 200-1 in the x direction. For example, the first chip pads 220-1 may be adjacent to a left edge in the x direction and may be arranged along the y direction. In detail, when the upper surface of the first semiconductor chip 200-1 has a rectangular shape, the first chip pads 220-1 may be adjacent to the left edge in the x direction corresponding to one side of the rectangular shape and may be arranged along the y direction. For example, the first chip pads 220-1 may be disposed to have a first pitch P1 in the y direction. The first chip pad 220-1 may be exposed from the first chip protection layer. Also, the first chip pad 220-1 may be directly electrically connected to the corresponding substrate pad 120 of the package substrate 100 through the conductive connection pattern 400.

The first semiconductor chip 200-1 may be adhered and fixed to and stacked on the upper surface of the package substrate 100 through an adhesive layer 250. The adhesive layer 250 may be, for example, a die attach film (DAF). However, the adhesive layer 250 is not limited to the DAF.

The second semiconductor chip 200-2 may be stacked on the first semiconductor chip 200-1 through the adhesive layer 250. Also, as the second semiconductor chip 200-2 is stacked in a stepped structure on the first semiconductor chip 200-1, the first chip pad 220-1 of the first semiconductor chip 200-1 may be exposed to the outside and may thus be directly electrically connected to the substrate pad 120 through the conductive connection pattern 400.

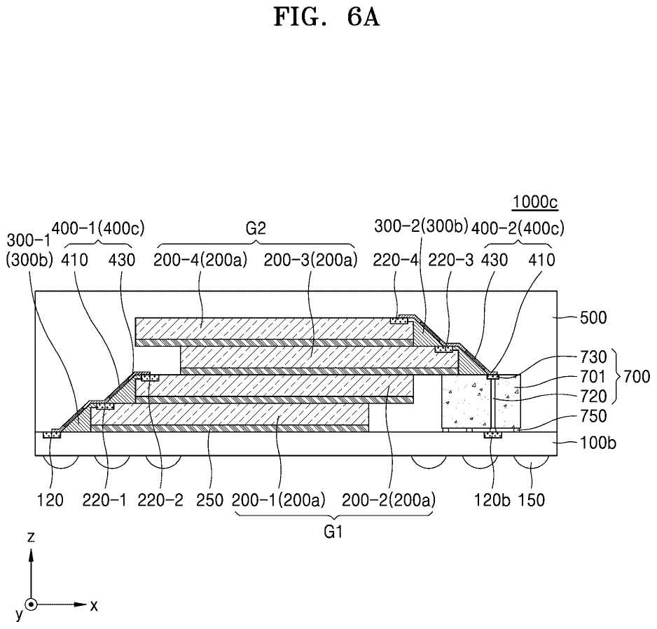

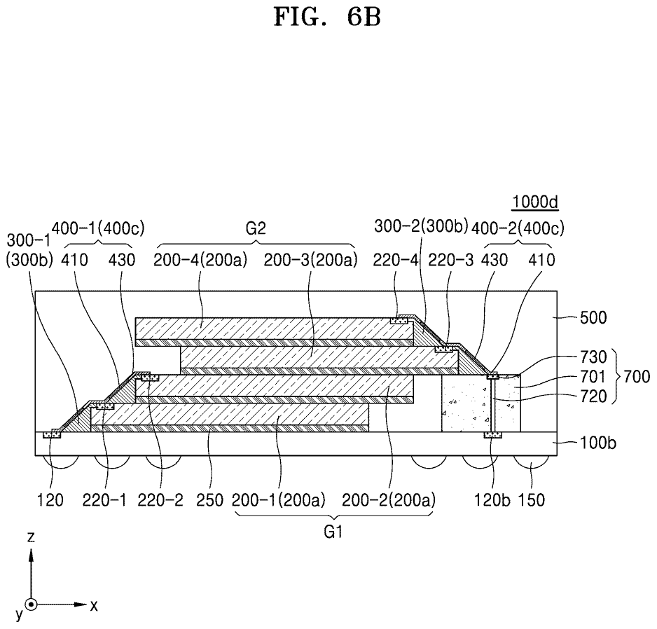

Moreover, when semiconductor chips are stacked in a stepped structure in only one direction, a width of a semiconductor package may excessively increase based on (due to) an increase in the number of semiconductor chips. Accordingly, when the number of semiconductor chips increases, semiconductor chips may be stacked in a composite stepped structure where a forward-direction stepped structure and a reverse-direction stepped structure are mixed. A structure where semiconductor chips are stacked in a composite stepped structure will be described in more detail in describing FIGS. 6A and 6B.

The side insulation layer 300 may be disposed on one surface of the semiconductor chip 200. The first side insulation layer 300 may include first and second insulation patterns 3001 and 3002. In detail, the first insulation pattern 3001 may be disposed on the package substrate 100 on a left side surface S1 of the first semiconductor chip 200-1 in the x direction, and moreover, the second insulation pattern 3002 may be disposed on the first semiconductor chip 200-1 and on a left side surface S1 of the second semiconductor chip 200-2. The side insulation layer 300 may extend in the y direction and may cover a left side surface S1 of a corresponding semiconductor chip 200 and a portion of an upper surface of another semiconductor chip 200 thereunder or the package substrate 100 where the corresponding semiconductor chip 200 is disposed. For example, the side insulation layer 300 may cover and be in contact with the left side surface S1 of the first semiconductor chip 200-1, a portion of the upper surface of the second semiconductor chip 200-2 and a portion of the upper surface of the package substrate 100.

In detail, the side insulation layer 300 may have a triangular pillar shape extending in the y direction, and as illustrated in FIG. 1A, a cross-sectional surface of the side insulation layer 300 perpendicular to the y direction may have a right-angled triangular shape. Also, a side surface of the side insulation layer 300 corresponding to a height of the right-angled triangular shape may contact a left side surface S1 of a corresponding semiconductor chip 200. Also, a lower surface of the side insulation layer 300 corresponding to a bottom side of the right-angled triangular shape may cover an upper surface of the package substrate 100 or an upper surface of another semiconductor chip 200 arranged under the corresponding semiconductor chip 200. Also, the lower surface of the side insulation layer 300 may be substantially coplanar with a lower surface of the adhesive layer 250 disposed on a lower surface of the semiconductor chip 200. For example, the lower surface of the second insulation pattern 3002 may be substantially coplanar with a lower surface of the adhesive which is disposed between the first and second semiconductor chips 200-1 and 200-2. The lower surface of the first insulation pattern 3001 may be substantially coplanar with the upper surface of the package substrate 100.

In the cross sectional view of FIG. 1A, the right-angled triangular shape may have two adjacent line segments and a hypotenuse segment extending between the two adjacent line segments, and the two adjacent line segments may form a right angle, and the hypotenuse segment may form an acute angle with respect to the upper surface of the package substrate. The line and hypotenuse segments, as described herein, refers to a physical or conceptual straight line extending between two points. In addition, the term ‘shape’ may encompass identicality or near-identicality such that the side insulation layer 300 may have a substantially right-angled triangular shape. For example, the actual geometry of the side insulation layer 300 in a cross sectional view may not be a perfect right-angled triangle, and its edges may not be strictly linear as depicted in FIG. 3.

Furthermore, as seen in FIG. 2A, the side insulation layer 300 may include an extension portion 300E which covers a portion of an upper surface of a corresponding semiconductor chip 200. The extension portion 300E may extend in the y direction and may cover an upper surface of the semiconductor chip 200 up to the left side surface S1 of the semiconductor chip 200 from the chip pad 220. In FIGS. 1B and 2B, a dotted line, which is adjacent to the chip pad 220 and extends in the y direction, of the side insulation layer 300 may correspond to a left side surface S1 of a corresponding semiconductor chip 200. Also, a portion of an upper surface, where the first chip pad 220-1 is disposed, of the first semiconductor chip 200-1 may not be covered by the side insulation layer 300.

For reference, a portion of an upper surface, covered by the extension portion 300E, of the semiconductor chip 200 may correspond to a portion of a scribe lane, which is a region formed between chips on a wafer for dicing, and which remains after singulation of the wafer into individual chips. Generally, a test pad for a test may be disposed in the scribe lane, and a portion of the test pad may remain in the remaining scribe lane. Therefore, the extension portion 300E may be formed for preventing short circuit between the conductive connection pattern 400 and the test pad.

As seen in FIGS. 1A and 1B, the side insulation layer 300 may be disposed between the semiconductor chip 200 and the sealant 500. Accordingly, in order to minimize a warpage of the semiconductor package 1000, the side insulation layer 300 may include a material having a coefficient of thermal expansion between a coefficient of thermal expansion of the sealant 500 and a coefficient of thermal expansion of the semiconductor chip 200 (e.g., up to a coefficient of thermal expansion of the sealant 500 from a coefficient of thermal expansion of the semiconductor chip 200). For example, in the semiconductor package 1000 according to an embodiment, the side insulation layer 300 may include a polymer, such as epoxy resin or other types of resin, which are widely used as adhesives or gap-filling materials (which may be referred to as under-fill material) in semiconductor packaging.

The conductive connection pattern 400 may directly electrically connect the chip pad 220 of the semiconductor chip 200 to the substrate pad 120 of the package substrate 100. In detail, the conductive connection pattern 400 may directly electrically connect the first chip pad 220-1 of the first semiconductor chip 200-1 and a second chip pad 220-2 of the second semiconductor chip 200-2 to the substrate pad 120 of the package substrate 100. Therefore, the conductive connection pattern 400 may contact the substrate pad 120 of the package substrate 100 and the chip pad 220 of the semiconductor chip 200, and may be in contact with and extend on a slope surface and the extension portion 300E of the side insulation layer 300. Here, the slope surface of the side insulation layer 300 may correspond to a hypotenuse of the right-angled triangular shape (or the hypotenuse segments of the right-angled triangular shapes of the first and second insulation patterns 3001 and 3002). The slope surface may include first and second sub-surfaces, which correspond to the first and second insulation patterns 3001 and 3002, respectively.

The conductive connection pattern 400 may include a straight line portion (a first portion having a linear shape) 410 and a bent line portion (a second portion having a bent shape) 430. The straight line portion 410 may include first and second straight line portions 410-1 and 410-2. For example, the conductive connection pattern 400 may include at least one straight line portion 410 and at least one bent line portion 430, which are physically and electrically connected in series. The straight line portion 410 may not be strictly linear. For example, the straight line portion 410 may be formed along the slope surface of the side insulation layer 300 such as the slightly curved slope surface of the underfilling material shown in FIG. 3. Accordingly, the straight line portion 410 may be a first portion having curvature less than the bent line portion (second portion) 430. In addition, the bent line portion 430 may be a second portion having more abrupt (e.g., angular) surface transition.

The straight line portion 410 may be disposed on the slope surface of the side insulation layer 300. The first and second straight line portions 410-1 and 410-2 may be disposed on the first and second sub-surfaces of the first and second insulation patterns 3001 and 3002, respectively. The first sub-surface may extend from an upper end of a left side surface S1 of the first semiconductor chip 200-1 to the upper surface of the package substrate 100, and the second sub-surface may extend from an upper end of the side surface of the second semiconductor chip 200-2 to an upper surface of the first semiconductor chip 200-1.

Also, the bent line portion 430 may be disposed at a portion of the slope surface of the side insulation layer 300 and a portion of the upper surface of the semiconductor chip 200, and/or may be disposed at a portion of the slope surface of the side insulation layer 300 and a portion of the upper surface of the package substrate 100. Furthermore, the bent line portion 430 may contact the substrate pad 120 of the package substrate 100 and the chip pad 220 of the semiconductor chip 200.

The straight line portion 410 and the bent line portion 430 may include or be formed of conductive ink. Also, the straight line portion 410 and the bent line portion 430 may have conductivity so as to transfer an electrical signal. However, the straight line portion 410 and the bent line portion 430 may have different physical characteristics, based on structures thereof.

FIG. 3 shows the physical stress contour in a cross sectional view in a structure where the side insulation layer 300 formed of a gap-filling material is disposed on the side surface of a semiconductor chip 200. FIG. 3 illustrates the distinction between abrupt and gradual surface transitions. As shown in the figures, the surface may be segmented based on curvature variation, where less abrupt regions exhibit a lower curvature change, and more abrupt regions exhibit a greater curvature change. The maximum curvature in a region forming a sharp corner may be significantly greater than that in a region following a substantially linear surface. The bent line portion 430 may be likely to experience cracking due to the high stress applied thereto. To provide a more detailed description, the bent line portion 430 may be high in possibility that a crack occurs because much stress is applied thereto, based on the structure thereof. For example, as seen in the simulation photograph of FIG. 3, in a case which stacks a semiconductor chip, when a side surface of the semiconductor chip is covered by an under-fill material, the maximum stress (MAX) of the under-fill material may occur in an upper portion of the side surface of the semiconductor chip. Accordingly, in a case where a conductive connection pattern is formed on the side insulation layer 300, stress may largely occur in an upper portion of the side surface of the semiconductor chip 200, namely, a portion where the conductive connection pattern is bent, and a defect such as a crack of the conductive connection pattern may occur in a corresponding portion, as compared to the slope surface region where the minimum stress (MIN) of the under-fill material may occur.

In the semiconductor package 1000 according to an embodiment, the conductive connection pattern 400 may be divided into the straight line portion 410 and the bent line portion 430. For example, the straight line portion 410 and the bent line portion 430 may be formed on and follow the surface transitions of the slope surface region and the abrupt region, respectively. The bent line portion 430 may be formed of a material that has higher flexibility for responding to stress than the straight line portion 410. For example, the material of the straight line portion 410 may have less flexibility than that of the bent line portion 430 and may have a higher electrical conductivity than that of the bent line portion 430. Also, the bent line portion 430 may be lower in electrical conductivity than the straight line portion 410 and may be greater in flexibility than the straight line portion 410.

The conductive connection pattern 400 may be formed through a direct printing process by using conductive ink or a conductive paste. Here, the direct printing process may include, for example, various printing processes such as ink-jet printing, dispensing printing, aerosol jet printing, electro-hydrodynamic (EHD) printing, and screen printing.

The conductive ink may denote that a conductive filler is dispersed in a vehicle and may denote ink where an after-printing curing layer has conductivity. The conductive ink may be an ink which becomes electrically conductive by an after-printing curing process. The conductive ink may be manufactured by mixing an additive, a solvent, and a resin with the conductive filler. The conductive filler may be referred to as a metal powder and may include silver (Ag), copper (Cu), nickel (Ni), carbon (C), and aluminum (Al). However, the kind of conductive filler is not limited to the materials described above. A content of the conductive filler may be about 80 wt. % or more in the conductive connection pattern 400. However, a content of the conductive filler is not limited thereto. In the semiconductor package 1000 according to an embodiment, the straight line portion 410 of the conductive connection pattern 400 may have higher content of the conductive filler (e.g., a higher percentage such as wt. % of the conductive filler) than the bent line portion 430, and thus, may have higher electrical conductivity than the bent line portion 430. However, in some embodiments, a content of the conductive filler of the straight line portion 410 may be substantially the same as that of the conductive filler of the bent line portion 430, with electrical and mechanical properties that may still be as described above.

The resin may configure the vehicle along with the solvent. For example, the resin and the solvent may facilitate printing the conductive filler. The resin may include, for example, epoxy, silicon, urethane, and polyimide-based resin. However, a material of the resin is not limited to the materials described above. The solvent may include, for example, an organic solvent.

The additive may be provided for adding various characteristics to the conductive connection pattern 400. For example, the additive may be added for adding characteristics such as flexibility, electrification prevention, and flow prevention during the printing process of the conductive connection pattern 400. In detail, in the semiconductor package 1000 according to an embodiment, the material of the bent line portion of the conductive connection pattern 400 may include an additive for increasing flexibility. The material of the bent line portion 430 may include an additive, whereas the material of the straight line portion 410 may not include the additive. As a detailed example, the bent line portion 430 may include matrix substance of polyurethane, fluorine rubber, or fluorine surfactant as the additive, and the material of the straight line portion 410 may not include the matrix substance. Accordingly, the flexibility of the bent line portion 430 may be grater that of the straight line portion 410. In some embodiments, the material of the bent line portion 430 may include the same additive at a higher concentration (e.g., 5 wt. %) compared to the material of the straight line portion 410 (e.g., 1 wt. %). The additive may be configured such that flexibility of the conductive connection pattern 400 increases as a content of the additive increases.

Furthermore, in the semiconductor package 1000 according to an embodiment, the substrate pads 120 of the package substrate 100 may be disposed along the y direction and may have a first pitch P1. Also, the chip pads 220 of the semiconductor chip 200 may be disposed along the y direction and may have the first pitch P1. Therefore, the conductive connection patterns 400 may extend in parallel to each other in the x direction, and moreover, may extend in the x direction while an equal interval with respect to an adjacent conductive connection pattern 400. As described above, in the semiconductor package 1000 according to an embodiment, the conductive connection pattern 400 may be formed through a direct printing process. Accordingly, a pitch of the chip pad 220 of the semiconductor chip 200 may largely decrease compared to a semiconductor package of a wire bonding structure. In other words, the semiconductor package of a wire bonding structure may have a limitation in reducing a pitch of the chip pad 220 for a wire bonding process. However, in the semiconductor package 1000 according to an embodiment, the direct printing process may be performed instead of the wire bonding process, and thus, a pitch of the chip pad 220 of the semiconductor chip 200 may be considerably reduced.

The sealant 500 may cover the side insulation layer 300, the conductive connection pattern 400, and upper surfaces and side surfaces of the first and second semiconductor chips 200-1 and 200-2 on the package substrate 100. The sealant 500 may have a certain thickness and may cover the upper surface of the second semiconductor chip 200-2. The sealant 500 may include thermocurable resin such as epoxy resin, thermoplastic resin such as polyimide, or resin including a reinforcing agent such as an inorganic filler. For example, the sealant 500 may include Ajinomoto build-up film (ABF), flame retardant 4 (FR-4), or bismaleimide triazine (BT). Also, the sealant 500 may include a molding material, such as epoxy mold compound (EMC), or a photosensitive material such as photoimagable encapsulant (PIE). However, a material of the sealant 500 is not limited to the materials described above.

The external connection terminal 150 may be disposed on the lower surface of the package substrate 100. For example, the external connection terminal 150 may be disposed on the external pad on the lower surface of the package substrate 100. The external connection terminal 150 may be electrically connected to a wiring of the package substrate 100 through the external pad. Also, the external connection terminal 150 may include a solder ball. However, according to embodiments, the external connection terminal 150 may include a filler and a solder. The semiconductor package 1000 according to an embodiment may be mounted on an external substrate such as a base substrate or an interposer through the external connection terminal 150.

In the semiconductor package 1000 according to an embodiment, the side insulation layer 300 may be disposed on a side surface of the semiconductor chip 200, the conductive connection pattern 400 may have a structure where the conductive connection pattern 400 is disposed on the side insulation layer 300, and the chip pad 220 of the semiconductor chip 200 may be directly electrically connected to the substrate pad 120 of the package substrate 100 through the conductive connection pattern 400. Therefore, in the semiconductor package 1000 according to an embodiment, a height of the semiconductor package may decrease compared to the semiconductor package of the wire bonding structure, based on the structure described above. In detail, in the semiconductor package 1000 according to an embodiment, a height of a semiconductor package may decrease by an amount equal to a loop height required for wire connections to the upper semiconductor chip in conventional wire bonding processes. Also, in the semiconductor package 1000 according to an embodiment, by using the conductive connection pattern 400 instead of a wire, a horizontal size of a semiconductor may decrease compared to the semiconductor package of the wire bonding structure.

Also, in the semiconductor package 1000 according to an embodiment, the conductive connection pattern 400 may include the straight line portion 410 and the bent line portion 430, and the bent line portion 430 may have high flexibility, and thus, a crack of the conductive connection pattern 400 may be effectively prevented.

In the semiconductor package 1000 according to an embodiment, the conductive connection pattern 400 may be formed just on the semiconductor chip 200 by a direct printing process, and thus, a fine pitch of the chip pad 220 may be implemented. Also, the conductive connection pattern 400 may be formed in contact with the upper surfaces of each of the package substrate 100, the semiconductor chip 200, and the side insulation layer 300, and thus, wire sweeping may not occur in a molding process (during forming the sealant to cover the semiconductor chip). Accordingly, a likelihood of a short circuit defect caused by wire sweeping in the semiconductor package of the wire bonding structure may be eliminated or reduced.

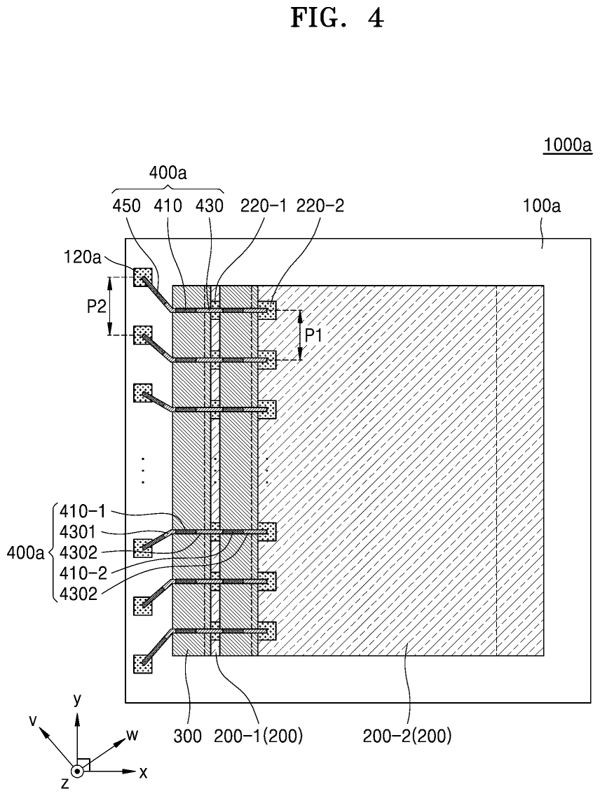

FIG. 4 is a plan view of a semiconductor package 1000a according to an embodiment. Descriptions which are the same as or similar to the descriptions of FIGS. 1A to 3 may be briefly given or may be omitted.

Referring to FIG. 4, arrangements of a substrate pad 120a and a conductive connection pattern 400a in the semiconductor package 1000a may differ from those of the semiconductor package 1000 of FIG. 1B. In detail, the semiconductor package 1000a according to an embodiment may include the package substrate 100a, a semiconductor chip 200, a side insulation layer 300, the conductive connection pattern 400a, and a sealant 500. The semiconductor chip 200, the side insulation layer 300, and the sealant 500 may be understood in accordance with the descriptions of the semiconductor package 1000 of FIGS. 1A to 2B.

As illustrated in FIG. 4, in the semiconductor package 1000a according to an embodiment, a substrate pad 120a of the package substrate 100a may be disposed apart from the side insulation layer 300. Also, the substrate pad 120a may be disposed to have a second pitch P2 in a y direction. The second pitch P2 may be greater than the first pitch P1 of the chip pad 220 of the semiconductor chip 200. Therefore, a structure of the conductive connection pattern 400a connecting the chip pad 220 of the semiconductor chip 200 to the substrate pad 120a of the package substrate 100a may differ from that of the conductive connection pattern 400 of the semiconductor package 1000 of FIG. 1B.

In detail, in the semiconductor package 1000a according to an embodiment, the conductive connection pattern 400a may include a straight line portion 410, a bent line portion 430, and a substrate line portion 450. The straight line portion 410 may include first and second straight line portions 410-1 and 410-2, and the bent line portion 430 may include a first bent line portion 4301 and second bent line portions 4302. The straight line portion 410 and the second bent line portion 4302 may be the same as those of the conductive connection pattern 400 of the semiconductor package 1000 of FIG. 1B. For example, the straight line portion 410 may be disposed on a slope surface of the side insulation layer 300 and may extend in an x direction. Also, the bent line portion 430 may be disposed at a portion of the slope surface of the side insulation layer 300 and a portion of an upper surface of the semiconductor chip 200, or may be disposed at a portion of the slope surface of the side insulation layer 300 and a portion of an upper surface of the package substrate 100 and may extend in the x direction.

Furthermore, the substrate line portion 450 may be disposed on an upper surface of the package substrate 100a and may extend in a diagonal direction (w direction or v direction) with a certain angle in the x direction. In detail, the substrate line portion 450 may extend in the diagonal direction from the first bent line portion 4301. The first bent line portion 4301 may be disposed at a portion of the slope surface of the side insulation layer 300 and a portion of the upper surface of the package substrate 100, and may have a bent shape in the y direction as well as the z direction. A pitch of the substrate pad 120a of the package substrate 100a may be greater than that of the chip pad 220 of the semiconductor chip 200, and thus, a plurality of substrate line portions 450 may progressively distance from each other toward the substrate pad 120a. For example, the length of substrate line portions 450 in contact with the package substrate 100a may increase from the center of an edge of the package substrate 100a toward both corner ends of the edge. The substrate line portion 450 may extend on an upper surface of the package substrate 100a, and thus, may be less susceptible to stress. Accordingly, the substrate line portion 450 may include substantially the same material as that of the straight line portion 410. However, in some embodiments, in terms of a manufacturing process (e.g., to simplify the manufacturing process), the substrate line portion 450 may include substantially the same material as that of the bent line portion 430. Also, in some embodiments, in terms of a manufacturing process and a resistance (e.g., to reduce the complexity of the manufacturing process and to reduce the resistance of the conductive connection pattern 400a), the substrate line portion 450 may be formed to have a width which is greater than the other portions.

In the semiconductor package 1000a according to an embodiment, a pitch of the substrate pad 120a of the package substrate 100a may be formed greater than a pitch of the chip pad 220 of the semiconductor chip 200. Therefore, the degree of freedom in arrangement of the substrate pad 120a and related components may increase. Also, a size of the substrate pad 120a may increase based on an increase in pitch, and thus, a formation process of the substrate pad 120a and a connection process between the substrate pad 120a and the conductive connection pattern 400a may be more easily performed. Moreover, the substrate line portion 450 may be formed through a direct printing process, and thus, similar to the semiconductor package 1000 of FIG. 1B, the conductive connection pattern 400a may be easily formed through a direct printing process.

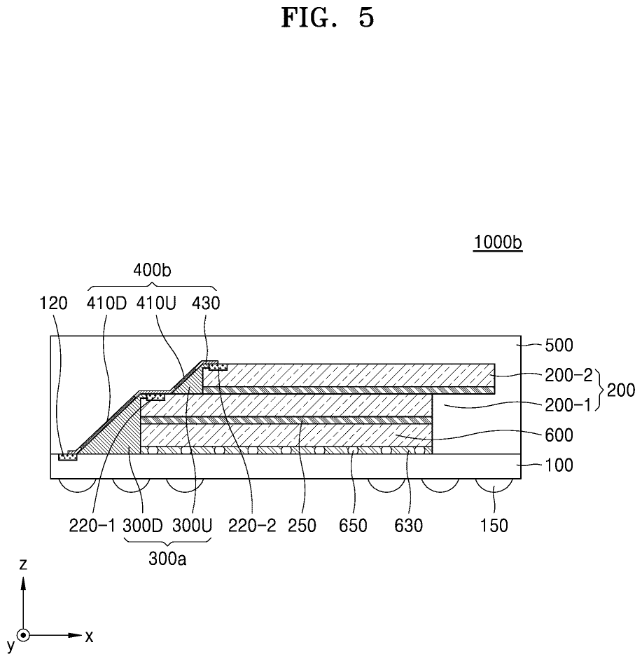

FIGS. 5 to 6B are cross-sectional views of a semiconductor package according to embodiments. Descriptions which are the same as or similar to the descriptions of FIGS. 1A to 4 may be briefly given or may be omitted.

Referring to FIG. 5, a semiconductor package 1000b according to an embodiment may further include a logic chip (logic semiconductor chip) 600, and thus, may differ from the semiconductor package 1000 of FIG. 1B. Also, based on (due to) the logic chip 600, a structure of each of a side insulation layer 300a and a conductive connection pattern 400b may be changed. In detail, the semiconductor package 1000b according to an embodiment may include a package substrate 100, a semiconductor chip 200, the side insulation layer 300a, the conductive connection pattern 400b, a sealant 500, and the logic chip 600. The package substrate 100, the semiconductor chip 200, and the sealant 500 may be understood in accordance with the descriptions of the semiconductor package 1000 of FIGS. 1A to 2B. In the semiconductor package 1000b according to an embodiment, the semiconductor chip 200 may be a memory chip (for example, a dynamic random access memory (DRAM) chip). However, the semiconductor chip 200 is not limited to the DRAM chip.

In the semiconductor package 1000b according to an embodiment, the logic chip 600 may be mounted on the package substrate 100 in a flip-chip bonding structure. In detail, the logic chip 600 may be mounted on the package substrate 100 through a connection terminal 650. An active layer may be disposed in a lower portion of the logic chip 600, and thus, a lower surface of the logic chip 600 may be an active surface, and an upper surface of the logic chip 600 may be an inactive surface. Also, a chip pad of the logic chip 600 may be disposed on the lower surface of the logic chip 600, and the connection terminal 650 may be disposed on the chip pad. An adhesive layer 630 may be filled between the logic chip 600 and the package substrate 100 and between connection terminals 650. The adhesive layer 630 may be, for example, a non-conductive film (NCF). However, the adhesive layer 630 is not limited to the NCF. In some embodiments, various resin materials used in an under-fill material may be used instead of the adhesive layer 630.

The logic chip 600 may include a plurality of logic devices in an integrated device layer of the active layer. The logic devices may be understood in accordance with the descriptions of the semiconductor package 1000 of FIG. 1B. The logic chip 600 may be a central processing unit (CPU) chip, a microprocessor unit (MPU) chip, a graphics processing unit (GPU), a neural processing unit (NPU) chip, a system-on-chip (SoC) chip, an application specific integrated circuit (ASIC) chip, an application processor (AP) chip, or a control chip.

The semiconductor chip 200 may be stacked on the logic chip 600 through the adhesive layer 250. Furthermore, a chip pad of the logic chip 600 may not be upward exposed. Accordingly, in terms of a reduction in size of the semiconductor package 1000b, a first semiconductor chip 200-1 may be disposed in a structure which entirely covers the logic chip 600. For example, a left side surface of the first semiconductor chip 200-1 may be substantially coplanar with a left side surface of the logic chip 600 in an x direction. However, in some embodiments, the first semiconductor chip 200-1 may be disposed in a stepped structure on the logic chip 600.

In FIG. 5, the logic chip 600 and the semiconductor chip 200 are illustrated as having the same size. However, a size of each of the logic chip 600 and the semiconductor chip 200 is not limited thereto. For example, the logic chip 600 and the semiconductor chip 200 may have different sizes. In this case, a right side surface of the first semiconductor chip 200-1 may not match a right side surface of the logic chip 600 in the x direction.

The side insulation layer 300a may include a lower side insulation layer 300D and an upper side insulation layer 300U. The first semiconductor chip 200-1 may be stacked on the logic chip 600 so that left side surfaces thereof match each other, instead of a stepped structure, and thus, as illustrated in FIG. 5, a size of the lower side insulation layer (lower side insulation pattern) 300D may be greater than that of the upper side insulation layer (upper side insulation pattern) 300U. For example, in the lower side insulation layer 300D, a cross-sectional surface thereof perpendicular to a y axis may have a right-angled triangular shape, and a side surface thereof corresponding to a height of the right-angled triangular shape may have a height substantially equal to a sum of a thickness of the first semiconductor chip 200-1 and a thickness of the logic chip 600.

The conductive connection pattern 400b may include a lower straight line portion 410D, an upper straight line portion 410U, and a bent line portion 430, which are formed on the side insulation layer 300a. The bent line portion 430 may be understood in accordance with the descriptions of the bent line portion 430 of the conductive connection pattern 400 of the semiconductor package 1000 of FIG. 1A. Though there may be a length difference, the lower straight line portion 410D and the upper straight line portion 410U may be understood in accordance with the descriptions of the straight line portion 410 of the conductive connection pattern 400 of the semiconductor package 1000 of FIG. 1A. The conductive connection pattern 400b may be formed on a slope surface, and have a lower portion and an upper portion. For example, the lower straight line portion 410D may be disposed on the lower portion (first sub-surface) of the slope surface and on the lower side insulation layer 300D, and the upper straight line portion 410U may be disposed on the lower portion (second sub-surface) of the slope surface and on the upper side insulation layer 300U. Also, the lower side insulation layer 300D may be greater in size than the upper side insulation layer 300U, and thus, the lower straight line portion 410D may be longer in length than the upper straight line portion 410U.

Referring to FIG. 6A, a semiconductor package 1000c according to an embodiment may further include an interposer 700, and moreover, a semiconductor chip 200a may be stacked in a composite stepped structure where a forward-direction stepped structure and a reverse-direction stepped structure are mixed. In this context, the semiconductor package 1000c may differ from the semiconductor package 1000 of FIG. 1B. Also, based on the composite stepped structure of the semiconductor chip 200a, a structure of each of a side insulation layer 300b and a conductive connection pattern 400c may be changed. In detail, the semiconductor package 1000c according to an embodiment may include a package substrate 100b, a semiconductor chip 200a, the side insulation layer 300b, the conductive connection pattern 400c, a sealant 500, and the interposer 700. The package substrate 100b and the sealant 500 may be understood in accordance with the descriptions of the semiconductor package 1000 of FIGS. 1A to 2B, except for second substrate pads 120b. In the semiconductor package 1000c according to an embodiment, the package substrate 100b may further include second substrate pads 120b which are disposed along a y direction on the right of the package substrate 100b such that each of the second substrate pads 120b is disposed adjacent to a pair of third chip pads 220-3 and on fourth chip pads 220-4 in an x direction. Also, the sealant 500 may cover and seal the interposer 700 and four semiconductor chips 200a on the package substrate 100b.

In the semiconductor package 1000c according to an embodiment, the semiconductor chip 200a may include a first semiconductor chip 200-1, a second semiconductor chip 200-2, a third semiconductor chip 200-3, and a fourth semiconductor chip 200-4. Here, the first semiconductor chip 200-1 and the second semiconductor chip 200-2 may constitute a first group G1 and may be stacked in a stepped structure in a forward direction, namely, in a right direction with respect to the x direction. Also, the third semiconductor chip 200-3 and the fourth semiconductor chip 200-4 may constitute a second group G2 and may be stacked in a stepped structure in a reverse direction, namely, in a left direction with respect to the x direction. For reference, in the third semiconductor chip 200-3, it may be described that a stepped structure is formed in a forward direction with respect to the second semiconductor chip 200-2, but for convenience of description, it may be described that the third semiconductor chip 200-3 has a reverse-direction stepped structure along with the fourth semiconductor chip 200-4. Furthermore, a chip pad 220 of each of the first and second semiconductor chips 200-1 and 200-2 of the first group G1 may be adjacent to a left edge thereof in the x direction and may be disposed in the y direction. On the other hand, a chip pad 220 of each of the third and fourth semiconductor chips 200-3 and 200-4 of the second group G2 may be adjacent to a right edge thereof in the x direction and may be disposed in the y direction.

The side insulation layer 300b may include a first side insulation layer 300-1 corresponding to the first group G1 of the semiconductor chip 200a and a second side insulation layer 300-2 corresponding to the second group G2 of the semiconductor chip 200a. The first side insulation layer 300-1 may be disposed on a left side surface of each of the first and second semiconductor chips 200-1 and 200-2 of the first group G1 in the x direction. Also, the second side insulation layer 300-2 may be disposed on a right side surface of each of the third and fourth semiconductor chips 200-3 and 200-4 of the second group G2 in the x direction. The side insulation layer 300b may be understood in accordance with the description of the side insulation layer 300 of the semiconductor package 1000 of FIG. 1A.

The conductive connection pattern 400c may include a first conductive connection pattern 400-1 corresponding to the first group G1 of the semiconductor chip 200a and a second conductive connection pattern 400-2 corresponding to the second group G2 of the semiconductor chip 200a. The first conductive connection pattern 400-1 may be disposed on the first side insulation layer 300-1, and the second conductive connection pattern 400-2 may be disposed on the second side insulation layer 300-2. The conductive connection pattern 400c may be understood in accordance with the description of the conductive connection pattern 400 of the semiconductor package 1000 of FIG. 1A. Also, in the second conductive connection pattern 400c-2, a bent line portion 430 may be disposed at a portion of a slope surface of the second side insulation layer 300-2 and a portion of an upper surface of the semiconductor chip 200a, or may be disposed at a portion of the slope surface of the second side insulation layer 300-2 and a portion of an upper surface of the interposer 700.

The interposer 700 may be mounted on the package substrate 100b through a connection terminal 750. The interposer 700 may be disposed at substantially the same height level as that of the combination of the first semiconductor chip 200-1 and the second semiconductor chip 200-2. The interposer 700 may have a height substantially equal to that of the first group G1 and may be disposed on the package substrate 100b at a right side of the first group G1 in the x direction. Based on an arrangement structure of the interposer 700, the semiconductor chip 200a (for example, the third semiconductor chip 200-3) of the second group G2 may be stacked on and partially overlap with the second semiconductor chip 200-2 and the interposer 700 in the z direction.

The interposer 700 may include an interposer body 701, a through via 720, and an interposer pad 730. The interposer body 701 may include, for example, silicon (Si). Therefore, the interposer 700 may be a Si-interposer. However, the interposer 700 is not limited to the Si-interposer. For example, the interposer 700 may be an organic or inorganic interposer.

The through via 720 may pass through the interposer body 701 and may extend in a z direction. When the interposer body 701 includes Si, the through via 720 may correspond to a through silicon via (TSV). The through via 720 may be connected to a connection terminal 750 on a lower surface of the interposer 700.

The interposer pad 730 may be disposed on an upper surface of the interposer body 701. The interposer pad 730 may be connected to the through via 720. Therefore, the through via 720 may directly electrically connect the interposer pad 730 to the connection terminal 750 on the lower surface of the interposer 700. The connection terminal 750 may be connected to a second substrate pad 120b of the package substrate 100b.

Therefore, the first and second semiconductor chips 200-1 and 200-2 of the first group G1 may be directly electrically connected to the substrate pad 120 of the package substrate 100b through the first conductive connection pattern 400-1. Also, the third and fourth semiconductor chips 200-3 and 200-4 of the second group G2 may be directly electrically connected to the interposer pad 730 of the interposer 700 through the second conductive connection pattern 400-2, and moreover, may be directly electrically connected to the second substrate pad 120b of the package substrate 100b through the connection terminal 750 and the through via 720 of the interposer 700.

Hereinabove, a structure where four semiconductor chips 200a are stacked has been described, but in the semiconductor package 1000c according to an embodiment, the number of semiconductor chips 200a is not limited to four. For example, the semiconductor package 1000c according to an embodiment, three or five or more semiconductor chips 200a may be stacked. Also, three or five or more semiconductor chips 200a may be grouped into the two groups G1 and G2 and may be directly electrically connected to the substrate pads 120 and 120b of the package substrate 100b through a corresponding conductive connection pattern 400c.

Referring to FIG. 6B, in a semiconductor package 1000d according to an embodiment, an interposer 700 may be stacked on a second substrate pad 120b of a package substrate 100b without a connection terminal, and thus, the semiconductor package 1000d may differ from the semiconductor package 1000c of FIG. 6B. In detail, the semiconductor package 1000d according to an embodiment may include the package substrate 100b, a semiconductor chip 200a, a side insulation layer 300b, a conductive connection pattern 400c, a sealant 500, and the interposer 700. The package substrate 100b, the semiconductor chip 200a, the side insulation layer 300b, the conductive connection pattern 400c, and the sealant 500 may be understood in accordance with the descriptions of the semiconductor package 1000c of FIG. 6B. The interposer 700 may have a height substantially equal to that of the first group G1, and the third and fourth chip pad 220-3 and 220-4 may be directly electrically connected to the second substrate pad 120b through the through via 720.

In the semiconductor package 1000d according to an embodiment, the interposer 700 may be stacked on the package substrate 100b without a connection terminal. For example, the interposer 700 may be stacked on the package substrate 100b through pad-to-pad bonding or hybrid copper bonding (HCB). HCB may denote bonding where pad-to-pad bonding and insulator-to-insulator bonding are mixed. Moreover, because a pad is generally formed of copper (Cu), pad-to-pad bonding may be referred to as Cu-to-Cu bonding. Furthermore, although not shown, a lower interposer pad each connected to the through via 720 and a protection layer may be disposed on a lower surface of the interposer 700. In HCB, the lower interposer pad may be bonded to the second substrate pad 120b of the package substrate 100b. Also, a protection layer of the interposer 700 may be bonded to a protection layer on an upper surface of the package substrate 100b.

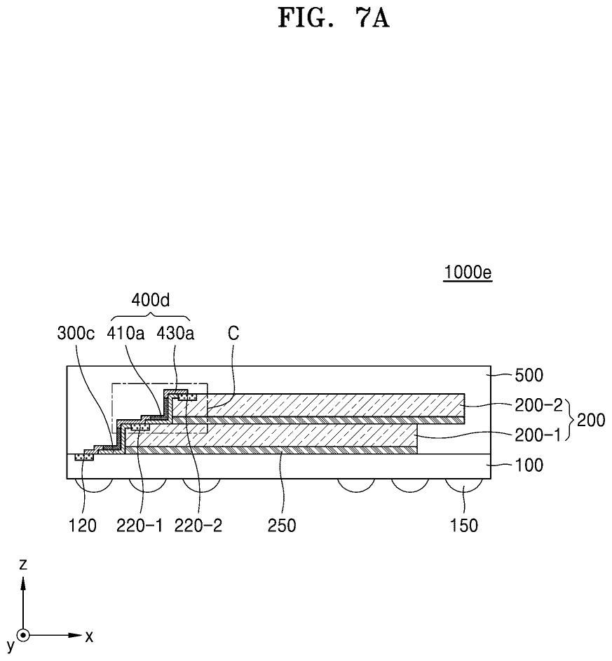

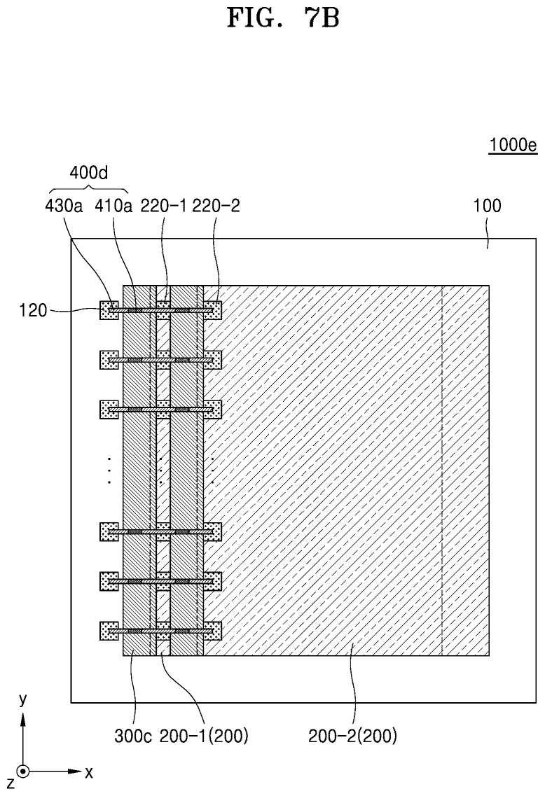

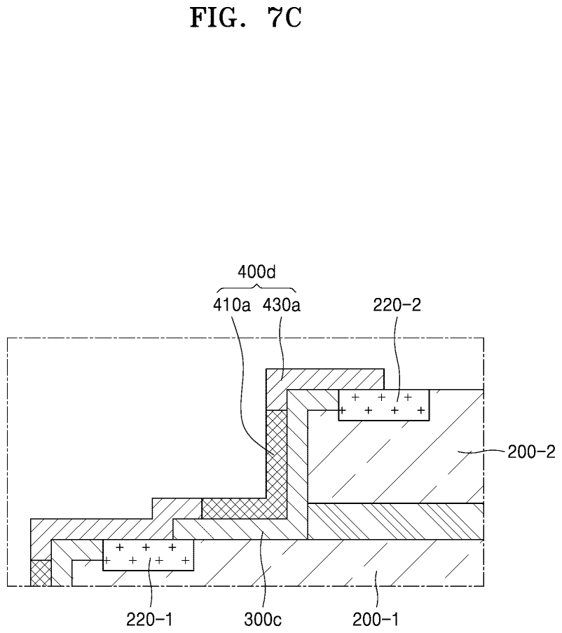

FIGS. 7A to 7C are a cross-sectional view, a plan view, and an enlarged cross-sectional view of a semiconductor package according to an embodiment. FIG. 7C illustrates an enlarged view of a region C of FIG. 7A. Descriptions which are the same as or similar to the descriptions of FIGS. 1A to 6B may be briefly given or may be omitted.

Referring to FIGS. 7A to 7C, in a structure of each of a side insulation layer 300c and a conductive connection pattern 400d, a semiconductor package 1000e according to an embodiment may differ from the semiconductor package 1000 of FIG. 1B. In detail, the semiconductor package 1000e according to an embodiment may include a package substrate 100a, a semiconductor chip 200, the side insulation layer 300c, the conductive connection pattern 400d, and a sealant 500. The package substrate 100, the semiconductor chip 200, and the sealant 500 may be understood in accordance with the descriptions of the semiconductor package 1000 of FIGS. 1A to 2B.

In the semiconductor package 1000e according to an embodiment, the side insulation layer 300c may cover a side surface and a portion of an upper surface of the semiconductor chip 200 and a portion of an upper surface of the package substrate 100 with a uniform thickness. In detail, based on (with respect to) a first semiconductor chip 200-1, the side insulation layer 300c may cover a left side surface of the first semiconductor chip 200-1, a portion of an upper surface of the first semiconductor chip 200-1, and a portion of the upper surface of the package substrate 100 with a uniform thickness. Also, the side insulation layer 300c may be bent in an L-shape at a boundary portion between the first semiconductor chip 200-1 and the package substrate 100.

Based on a second semiconductor chip 200-2, the side insulation layer 300c may cover a left side surface of the second semiconductor chip 200-2, a portion of an upper surface of the second semiconductor chip 200-2, and a portion of the upper surface of the first semiconductor chip 200-1 with a uniform thickness. Also, the side insulation layer 300c may be bent in an L-shape at a boundary portion between the second semiconductor chip 200-2 and the first semiconductor chip 200-1. Furthermore, as seen in FIG. 7B, a portion of an upper surface, where a first chip pad 220-1 is disposed, of the first semiconductor chip 200-1 may not be covered by the side insulation layer 300c. For example, the side insulation layer 300c may be formed to partially cover the first chip pad 220-1 of the first semiconductor chip 200-1. The side insulation layer 300c may be understood in accordance with the description of the side insulation layer 300 of the semiconductor package 1000 of FIG. 1A.

In the semiconductor package 1000e according to an embodiment, a conductive connection pattern 400d may include a first portion 410a and a second portion 430a. The first portion 410a may be disposed on the side insulation layer 300c. The second portion 430a may be disposed on a portion of the side insulation layer 300c and the chip pad 220, or may be disposed on a portion of the side insulation layer 300c and a substrate pad 120.

In detail, the first portion 410a may be disposed at the corner between the first semiconductor chip 200-1 and second semiconductor chip 200-2, and may be in contact with portions of the side insulation layer 300c interposed between the first portion 410a and each of the first semiconductor chip 200-1 and second semiconductor chip 200-2. For example, based on (with respect to) the second semiconductor chip 200-2, the first portion 410a may be disposed on the side insulation layer 300c corresponding to a portion of an upper surface of the first semiconductor chip 200-1 and a left side surface of the second semiconductor chip 200-2 in an x direction. Also, based on (due to) a structure of the side insulation layer 300c, the first portion 410a may be bent in an L-shape and disposed at a boundary portion between the first semiconductor chip 200-1 and the package substrate 100. Based on the second semiconductor chip 200-2, the first portion 410a may be disposed on the side insulation layer 300c corresponding to a portion of an upper surface of the first semiconductor chip 200-1 and a left side surface of the second semiconductor chip 200-2 in the x direction. Also, based on the structure of the side insulation layer 300c, the first portion 410a may be bent in an L-shape at a boundary portion between the first semiconductor chip 200-1 and the second semiconductor chip 200-2.

The second portion 430a may be disposed at an edge where the upper and side surfaces of the second semiconductor chip 200-2 meet and an edge where the upper and side surfaces of the first semiconductor chip 200-1 meet. Furthermore, the second portion 430a may be in contact with the substrate pad 120 and the chip pads 220. For example, based on the first semiconductor chip 200-1, the second portion 430a may be disposed on the first chip pad 200-1 and the side insulation layer 300c corresponding to a portion of the upper surface of the first semiconductor chip 200-1 and a left side surface of the first semiconductor chip 200-1 in the x direction. Also, the second portion 430a may be disposed on the substrate pad 120 and the side insulation layer 300c corresponding to a portion of an upper surface of the package substrate 100. Based on the second semiconductor chip 200-2, the second portion 430a may be disposed on the second chip pad 220-2 and the side insulation layer 300c corresponding to a portion of an upper surface of the second semiconductor chip 200-2 and a portion of a left side surface of the second semiconductor chip 200-2 in the x direction. The conductive connection pattern 400d may be understood in accordance with the description of the conductive connection pattern 400 of the semiconductor package 1000 of FIG. 1A.

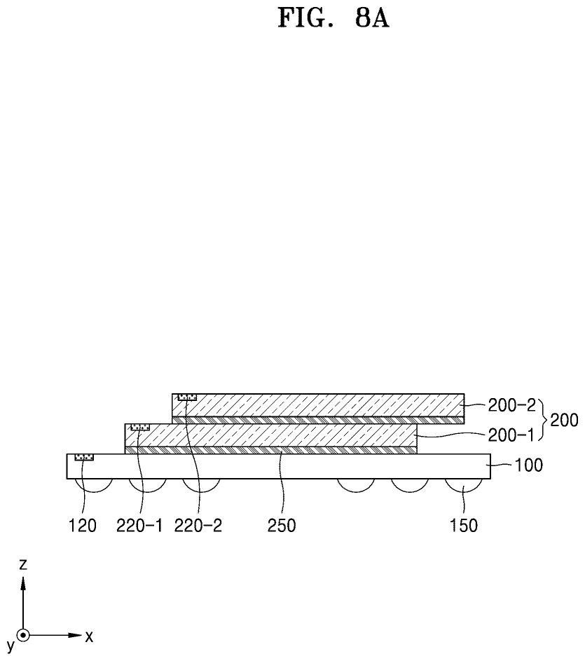

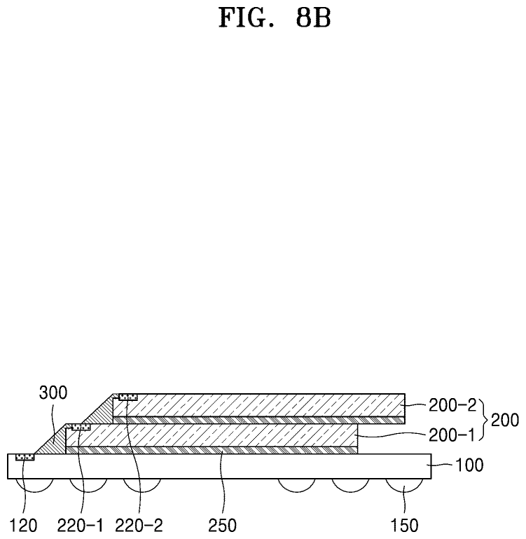

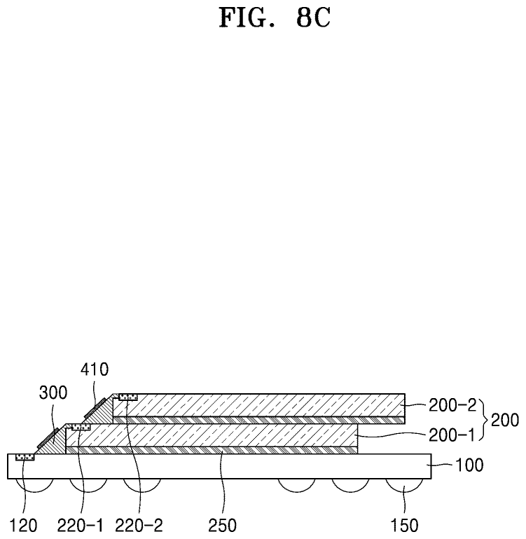

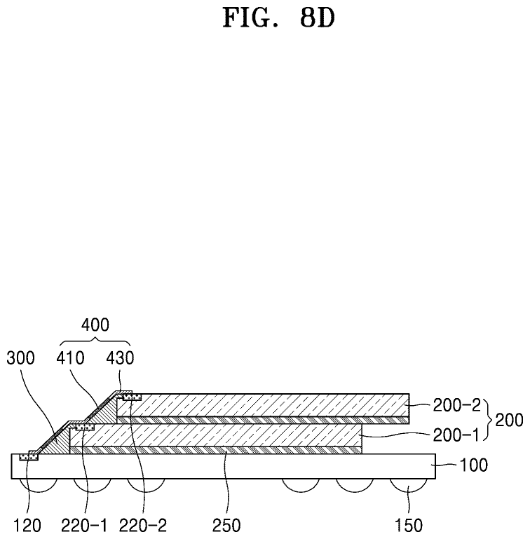

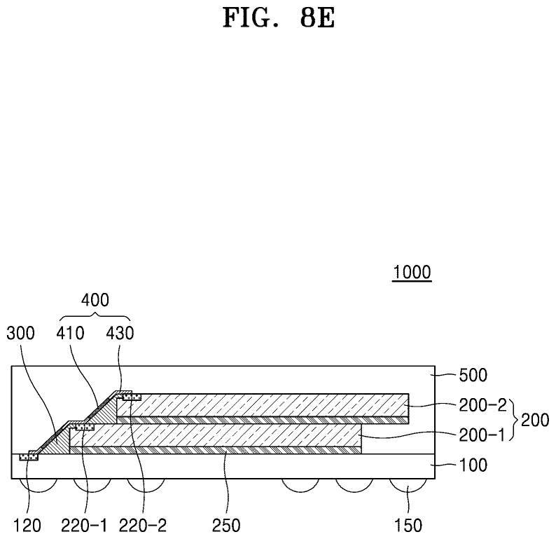

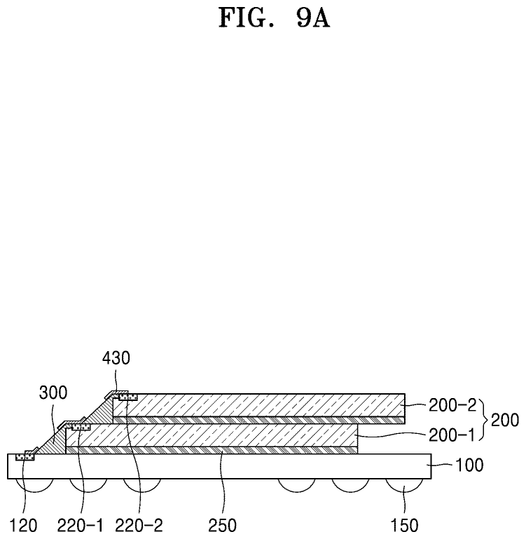

FIGS. 8A to 8E are cross-sectional views illustrating a process of a method of manufacturing a semiconductor package, according to an embodiment. FIGS. 8A to 8E may be described with reference to FIGS. 1A to 2B, and descriptions which are the same as or similar to the descriptions of FIGS. 1A to 7C may be briefly given or may be omitted.

Referring to FIG. 8A, a method of manufacturing a semiconductor package according to an embodiment, a semiconductor chip 200 may be stacked on a package substrate 100 in a stepped structure. A substrate pad 120 may be disposed on an upper surface of the package substrate 100. The substrate pads 120 may be adjacent to a left edge of the package substrate 100 in an x direction and may be disposed along a y direction. An external connection terminal 150 may be disposed on a lower surface of the package substrate 100. The package substrate 100 may be understood in accordance with the description of the package substrate 100 of the semiconductor package 1000 of FIG. 1A.

The semiconductor chips 200 may include the first semiconductor chip 200-1 and the second semiconductor chip 200-2. The first semiconductor chip 200-1 may be stacked on the package substrate 100 through an adhesive layer 250, and the second semiconductor chip 200-2 may be stacked on the first semiconductor chip 200-1 through the adhesive layer 250. The second semiconductor chip 200-2 may be stacked on the first semiconductor chip 200-1 in a stepped structure on the right in the x direction.

A chip pads 220 of the semiconductor chip 200 may be adjacent to a left edge of the semiconductor chip 200 in the x direction and may be disposed along the y direction, on an upper surface of the semiconductor chip 200. As the second semiconductor chip 200-2 is stacked on the first semiconductor chip 200-1 in a stepped structure, a first chip pad 220-1 of the first semiconductor chip 200-1 may be exposed at an upper surface of the first semiconductor chip 200-1. The semiconductor chip 200 may be understood in accordance with the description of the semiconductor chip 200 of the semiconductor package 1000 of FIG. 1A.

Referring to FIG. 8B, after the semiconductor chip 200 is stacked, a side insulation layer 300 may be formed on a side surface of the semiconductor chip 200. The side insulation layer 300 may extend in the y direction and may cover a left side surface of a corresponding semiconductor chip 200 and a portion of an upper surface of another semiconductor chip 200 under the corresponding semiconductor chip 200. The side insulation layer 300 may cover the package substrate 100 where the corresponding semiconductor chip 200 is disposed. In detail, the side insulation layer 300 may have a triangular pillar shape extending in the y direction, and as illustrated in FIG. 8B, a cross-sectional surface of the side insulation layer 300 perpendicular to the y direction may have a right-angled triangular shape. Also, a side surface of the side insulation layer 300 corresponding to a height of the right-angled triangular shape may contact a left side surface of a corresponding semiconductor chip 200. Also, a lower surface of the side insulation layer 300 corresponding to a bottom side of the right-angled triangular shape may cover an upper surface of a semiconductor chip 200 disposed under the side insulation layer 300. The lower surface of the side insulation layer 300 may cover an upper surface of the package substrate 100 where a corresponding semiconductor chip 200 is disposed. Furthermore, a side insulation layer 300 may include an extension portion 300E which covers a portion of an upper surface of a corresponding semiconductor chip 200.

The side insulation layer 300 may be formed through, for example, a dispensing process. Also, in the dispensing process, the side insulation layer 300 may be formed in a three-angled pillar shape by appropriately adjusting a content and/or viscosity of the side insulation layer 300. However, a shape of the side insulation layer 300 is not limited to the three-angled pillar shape. For example, in some embodiments, the side insulation layer 300 may be formed in a shape having a uniform thickness as shown in the semiconductor package 1000e of FIG. 7A.

Referring to FIG. 8C, after the side insulation layer 300 is formed, a straight line portion 410 of a conductive connection pattern 400 may be formed on a slope surface of the side insulation layer 300. The straight line portion 410 may be formed through a direct printing process.

Subsequently, referring to FIG. 8D, a bent line portion 430 may be formed at a portion of the upper surface of the side insulation layer 300, a portion of the upper surface of the semiconductor chip 200, and a portion of the upper surface of the package substrate 100. The bent line portion 430 may also be formed through the direct printing process. As a result, a conductive connection pattern 400 may be formed to include the bent line portion 430 and straight line portion 410. The direct printing process and the material and shape of the conductive connection pattern 400 may be understood in accordance with the descriptions of the conductive connection pattern 400 of the semiconductor package 1000 of FIG. 1A.

Referring to FIG. 8E, after the conductive connection pattern 400 is formed, a sealant 500 sealing the semiconductor chip 200 may be formed on the package substrate 100. The sealant 500 may be understood in accordance with the descriptions of the sealant 500 of the semiconductor package 1000 of FIG. 1A. The semiconductor package 1000 of FIG. 1A may be finished by forming the sealant 500.

Furthermore, in a process of FIG. 8A, in a case where the semiconductor chip 200 is stacked on the package substrate 100a including the substrate pad 120a which is greater in pitch than the chip pad 220, the semiconductor package 1000a of FIG. 4 may be manufactured as discussed with reference to FIGS. 8B to 8E. Moreover, in a process of FIG. 8C, a substrate line portion 450 of FIG. 4 may be further formed along with the straight line portion 410. Also, in a process of FIG. 8A, in a case where a logic chip 600 is stacked on the package substrate 100 before the semiconductor chip 200 is stacked, and the semiconductor chip 200 is stacked on the logic chip 600 in a stepped structure, the semiconductor package 1000b of FIG. 5 may be manufactured as discussed with reference to FIGS. 8B to 8E.

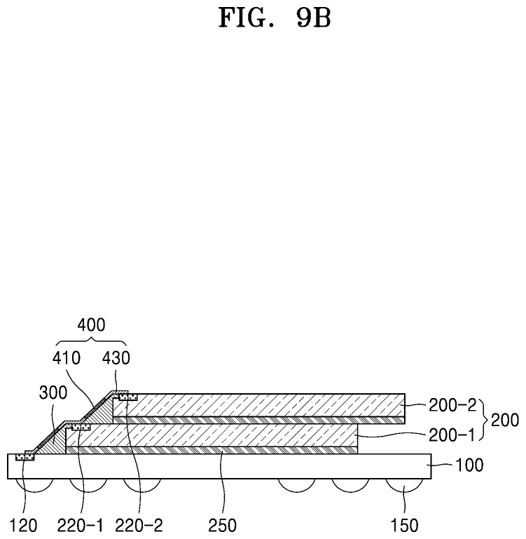

FIGS. 9A and 9B are cross-sectional views illustrating a process of a method of manufacturing a semiconductor package, according to an embodiment. FIGS. 8A to 8E may be described with reference to FIGS. 1A to 2B, and descriptions which are the same as or similar to the descriptions of FIGS. 8A to 8E may be briefly given or may be omitted.

Referring to FIG. 9A, in a method of manufacturing a semiconductor package according to an embodiment, a side insulation layer 300 may be formed on a side surface of a semiconductor chip 200 through the process of FIGS. 8A and 8B. Subsequently, a bent line portion 430 may be formed at a portion of an upper surface of the side insulation layer 300, a portion of an upper surface of the semiconductor chip 200, and a portion of an upper surface of a package substrate 100. The bent line portion 430 may also be formed through a direct printing process.

Subsequently, referring to FIG. 9B, a straight line portion 410 of a conductive connection pattern 400 may be formed on a slope surface of the side insulation layer 300. The straight line portion 410 may be formed through a direct printing process. As a result, the conductive connection pattern 400 may be formed to include the straight line portion 410 and the bent line portion 430. Subsequently, the semiconductor package 1000 of FIG. 1A may be finished through the process of FIG. 8E. As discussed above, in association with formation of the conductive connection pattern 400, a sequence for forming the straight line portion 410 and the bent line portion 430 may be arbitrary.

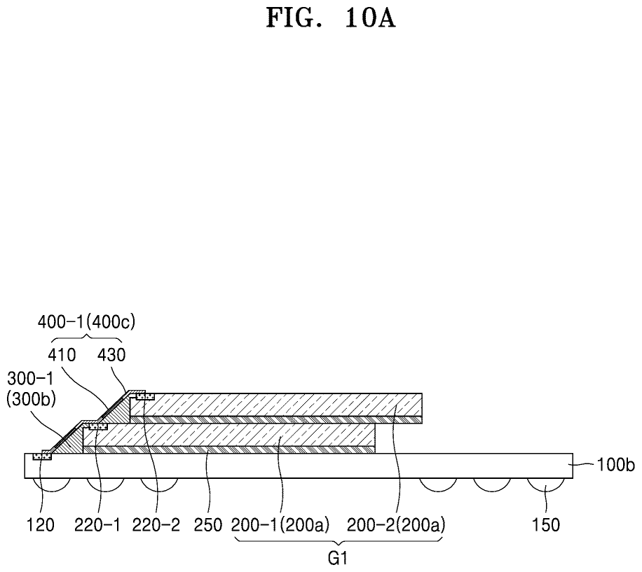

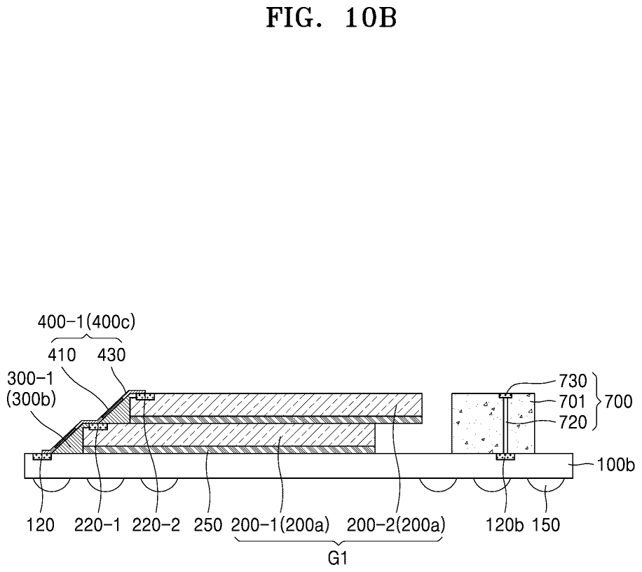

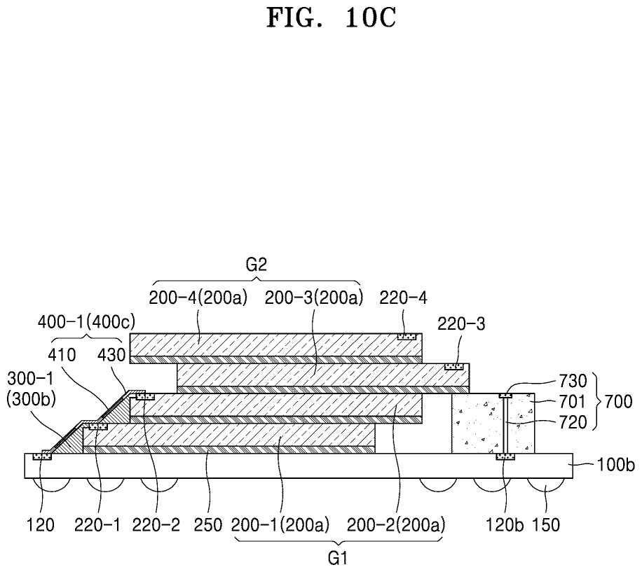

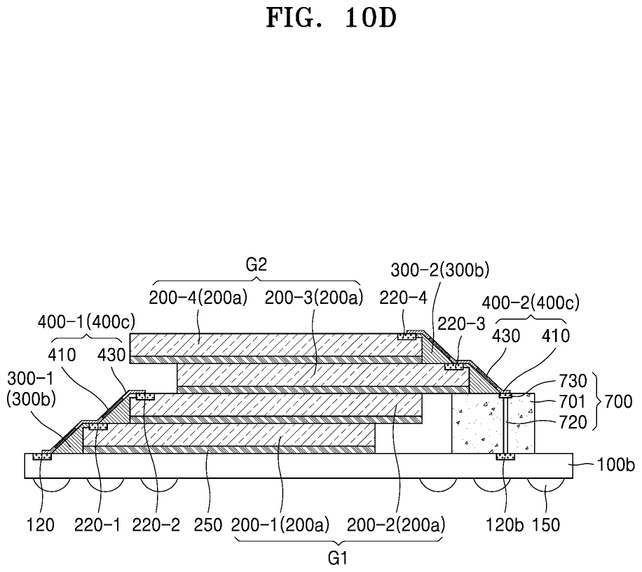

FIGS. 10A to 10D are cross-sectional views illustrating a process of a method of manufacturing a semiconductor package, according to an embodiment. FIGS. 10A to 10D may be described with reference to FIGS. 6A and 6B, and descriptions which are the same as or similar to the descriptions of FIGS. 8A to 8E may be briefly given or may be omitted.

Referring to FIG. 10A, in a method of manufacturing a semiconductor package according to an embodiment, semiconductor chips 200-1 and 200-2 of a first group G1 may be stacked on a package substrate 100b in a stepped structure, and a first side insulation layer 300-1 and a first conductive connection pattern 400-1 may be formed, through the process of FIGS. 8A to 8D or the process of FIGS. 9A and 9B. In detail, the semiconductor chips 200-1 and 200-2 of the first group G1 may be stacked in a stepped structure in a forward direction, namely, in a right direction with respect to an x direction. The first side insulation layer 300-1 may be disposed on a left side surface of each of the first and second semiconductor chips 200-1 and 200-2 of the first group G1 in the x direction. Also, the first conductive connection pattern 400-1 may be formed on the first side insulation layer 300-1.

Subsequently, referring to FIG. 10B, an interposer 700 may be mounted on the package substrate 100b. The interposer 700, as illustrated in FIG. 10B, may be disposed on the package substrate 100b of a right side of the first group G1 in the x direction.

The interposer 700, for example, may be mounted on the package substrate 100b through pad-to-pad bonding or HCB. However, a process of mounting the interposer 700 is not limited thereto. For example, the interposer 700 may be mounted on the package substrate 100b through a connection terminal 750. The interposer 700 may be understood in accordance with the descriptions of the semiconductor packages 1000c and 1000d of FIGS. 6A and 6B.

Referring to FIG. 10C, after the interposer is mounted, semiconductor chips 200-3 and 200-4 of a second group G2 may be stacked on the second semiconductor chip 200-2 and the interposer 700 in a stepped structure. As described above, the semiconductor chips 200-1 and 200-2 of the first group G1 may be stacked in a stepped structure in a forward direction, namely, in a right direction with respect to the x direction, and the semiconductor chips 200-3 and 200-4 of the second group G2 may be stacked in a stepped structure in a reverse direction, namely, in a left direction with respect to the x direction.

Referring to FIG. 10D, after the semiconductor chips 200-3 and 200-4 of the second group G2 are stacked, a second side insulation layer 300-2 and a second conductive connection pattern 400-2 may be formed, through the process of FIGS. 8B to 8E or the process of FIGS. 9A and 9B. In detail, the second side insulation layer 300-2 may be disposed on a right side surface of each of the semiconductor chips 200-3 and 200-4 of the second group G2 in the x direction. Also, the second conductive connection pattern 400-2 may be formed on the second side insulation layer 300-2.

Subsequently, the semiconductor package 1000d of FIG. 6B may be finished by forming a sealant 500 sealing the semiconductor chip 200a on the package substrate 100b. Also, in the process of FIG. 10A, in a case where the interposer 700 is mounted on the package substrate 100b through a connection terminal 750, the sealant 500 may be formed as discussed with reference to FIGS. 10B to 10D, and thus, the semiconductor package 1000c of FIG. 6A may be finished.

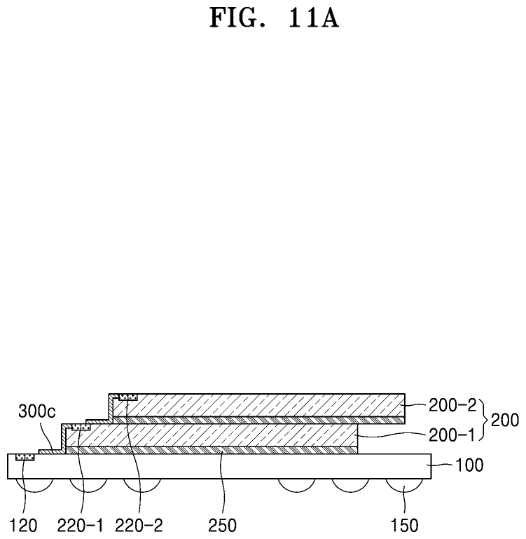

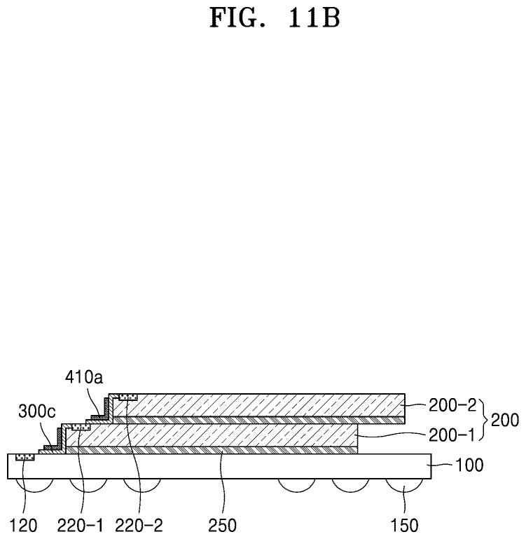

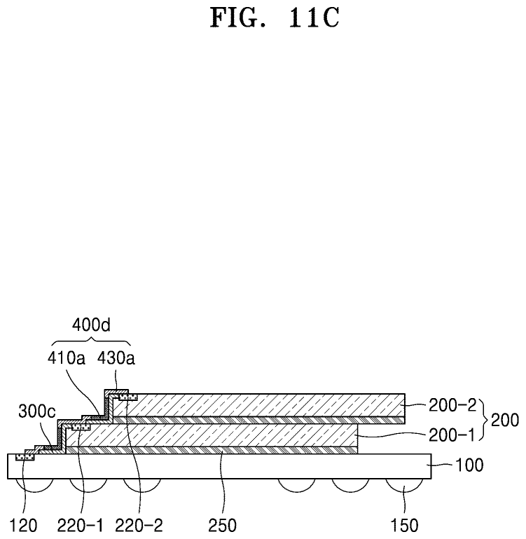

FIGS. 11A to 11C are cross-sectional views illustrating a process of a method of manufacturing a semiconductor package, according to an embodiment. FIGS. 11A to 11C may be described with reference to FIGS. 7A to 7C, and descriptions which are the same as or similar to the descriptions of FIGS. 8A to 8E may be briefly given or may be omitted.

Referring to FIG. 11A, a method of manufacturing a semiconductor package according to an embodiment, a semiconductor chip 200 may be stacked on a package substrate 100 in a stepped structure through the process of FIG. 8A. Subsequently, a side insulation layer 300c may be formed conformally on a side surface and a portion of an upper surface of the semiconductor chip 200 and a portion of an upper surface of the package substrate 100. For example, the side insulation layer 300c, which covers the side surface and a portion of the upper surface of the semiconductor chip 200 and a portion of the upper surface of the package substrate 100 with a uniform thickness, may be formed through a dispensing process. The side insulation layer 300c may be understood in accordance with the description of the semiconductor package 1000e of FIG. 7A.

Referring to FIG. 11B, after the side insulation layer 300c is formed, a first portion 410a may be formed through the process of FIG. 8C. However, because the side insulation layer 300c differs from a shape of the side insulation layer 300 of FIG. 8C, the first portion 410a may differ from a shape of the straight line portion 410 of FIG. 8C.

Subsequently, referring to FIG. 11C, a second portion 430a may be formed through the process of FIG. 8D. Also, based on a shape of the side insulation layer 300c, the bent line portion 430a may differ from a shape of the bent line portion 430 of FIG. 8D. As a result, a conductive connection pattern 400c may be formed to include the first portion 410a and the second portion 430a. In forming the conductive connection pattern 400c, as in FIGS. 9A and 9B, the second portion 430a may be first formed, and then, the first portion 410a may be formed.

Subsequently, the semiconductor package 1000e of FIG. 7A may be finished by forming a sealant 500 sealing the semiconductor chip 200 on the package substrate 100.

Hereinabove, exemplary embodiments have been described in the drawings and the specification. Embodiments have been described by using the terms described herein, but this has been merely used for describing the inventive concept and has not been used for limiting a meaning of the terms or limiting the scope of the inventive concept defined in the following claims. Therefore, it may be understood by those of ordinary skill in the art that various modifications and other equivalent embodiments may be implemented from the inventive concept. Accordingly, the scope of the invention is defined by the following claims.

While the inventive concept has been particularly shown and described with reference to embodiments thereof, it will be understood that various changes in form and details may be made to the embodiments without departing from the spirit and scope of the following claims.

What is claimed is:

1. A semiconductor package comprising:
a package substrate;
first and second semiconductor chips stacked on the package substrate in a stepped configuration, wherein the first semiconductor chip of the first and second semiconductor chips has a first side surface and the second semiconductor chip of the first and second semiconductor chips has a second side surface;
a first side insulation layer disposed on the first and second side surfaces of the first and second semiconductor chips, the first side insulation layer having a first slope surface; and
a first conductive connection pattern:
electrically connecting the first and second semiconductor chips to the package substrate,
in contact with the first slope surface of the first side insulation layer,
disposed on the first and second semiconductor chips, and
disposed on the package substrate,
wherein the first conductive connection pattern comprises:
a first portion formed of a first conductive material, and
a second portion formed of a second conductive material different from the first conductive material,
wherein the first and second portions are directly electrically connected to each other in series, and
wherein an electrical conductivity of the first portion is greater than an electrical conductivity of the second portion.

2. The semiconductor package of claim 1, wherein:
the first portion has a linear shape,
the second portion has a bent shape, and
flexibility of the second conductive material is greater than flexibility of the first conductive material.

3. The semiconductor package of claim 2, wherein the first and second conductive materials comprise a conductive filler, a resin, and an additive,
the first conductive material has a higher content of the conductive filler than does the second conductive material,
the second conductive material has a higher content of the additive than does the first conductive material, and
the additive is configured such that flexibility of the first conductive material increases as a content of the additive increases.

4. The semiconductor package of claim 1, wherein:
the first side insulation layer has first and second insulation patterns,
the first insulation pattern is in contact with the first side surface,
the second insulation pattern is in contact with the second side surface,
each of the first and second insulation patterns is configured to have a triangular pillar shape,
in a cross sectional view, each of the first insulation pattern and the second insulation pattern is configured to have a right-angled triangular shape,
in the cross sectional view, the right-angled triangular shape has two adjacent line segments and a hypotenuse segment extending between the two adjacent line segments, the two adjacent line segments are perpendicular to each other, and the hypotenuse segment is at an acute angle to an upper surface of the package substrate,
the first and second semiconductor chips and the first and second insulation patterns are arranged such than each of the first and second side surfaces is configured to be in contact with one of corresponding two of the adjacent line segments,
the first slope surface of the first side insulation layer includes first and second sub-surfaces each of which is configured to correspond to one of the hypotenuse segments of the right-angled triangular shapes,
the first and second sub-surfaces extend:
one from an upper end of the first side surface to an upper surface of the second semiconductor chip, and
the other from an upper end of the second side surface to the upper surface of the package substrate,
the first portion of the first conductive connection pattern is in contact with the first slope surface of the first side insulation layer, and
the second portion of the first conductive connection pattern is in contact with:
the first sub-surface of the first slope surface and the first semiconductor chip, or
the second sub-surface of the first slope surface and the package substrate.

5. The semiconductor package of claim 4, wherein:
the second portion of the first conductive connection pattern is in contact with the first portion of the first conductive connection pattern, and
the second portion of the first conductive connection pattern is in contact with:
a chip pad of one of the first and second semiconductor chips, or
a substrate pad of the package substrate.

6. The semiconductor package of claim 4, wherein:
the first insulation pattern comprises a first extension portion in contact with an upper surface of the first semiconductor chip,
the first extension portion extends from a first chip pad of the first semiconductor chip up to the first side surface of the of the first semiconductor chip,
the second insulation pattern comprises a second extension portion in contact with an upper surface of the second semiconductor chip,
the second extension portion extends from a second chip pad of the second semiconductor chip up to the second side surface of the of the second semiconductor chip, and
the second portion is in contact with:
the first slope surface of the first side insulation layer, and
one of the first and second extension portions.

7. The semiconductor package of claim 4, wherein:
among the first and second semiconductor chips, an adhesive is disposed, and
lower surfaces of the first and second insulation patterns:
one is coplanar with a lower surface of the adhesive, or
the other is coplanar with the upper surface of the package substrate.

8. The semiconductor package of claim 1, further comprising a sealant sealing the first and second semiconductor chips, on the package substrate,
wherein the first side insulation layer has a coefficient of thermal expansion, which is between a coefficient of thermal expansion of the sealant and a coefficient of thermal expansion of each of the first and second semiconductor chips.

9. The semiconductor package of claim 8, wherein the first side insulation layer comprises an epoxy.

10. The semiconductor package of claim 1, further comprising:
third and fourth semiconductor chips stacked on the package substrate in a stepped configuration, wherein the third and fourth semiconductor chips have third and fourth side surfaces, respectively;
a second side insulation layer in contact with the third and fourth side surfaces, the second side insulation layer having a second slope surface;
an interposer disposed on the package substrate; and
a second conductive connection pattern electrically connecting the third and fourth semiconductor chips to the package substrate, the second conductive connection pattern being in contact with the second slope surface of the second side insulation layer, the second conductive connection pattern being disposed on the third and fourth semiconductor chips, and the second conductive connection pattern being disposed on the package substrate,
wherein:
the second conductive connection pattern comprises:
a third portion formed of a third conductive material, and
a fourth portion formed of a fourth conductive material different from the third conductive material,
the third and fourth portions are directly electrically connected to each other in series,
an electrical conductivity of the third portion is greater than an electrical conductivity of the fourth portion,
the first and second semiconductor chips are disposed below the third and fourth semiconductor chips,
an upper one of the first and second semiconductor chips is offset laterally from a lower one of the first and second semiconductor chips in a first direction,
an upper one of the third and fourth semiconductor chips is offset laterally from a lower one of the third and fourth semiconductor chips in a second direction opposite to the first direction,
the lower one of the third and fourth semiconductor chips partially overlaps the upper one of the first and second semiconductor chips, and
the upper one of the first and second semiconductor chips is disposed between the lower one of the first and second semiconductor chips and the lower one of the third and fourth semiconductor chips.

11. The semiconductor package of claim 10, wherein:
the package substrate has a first edge and a second edge,
the first direction extends from the first edge to the second edge,
the first side insulation layer is closer to the first edge than the second side insulation layer,
the interposer is disposed closer to the second edge than the first edge, and the second conductive connection pattern is directly electrically connected to a second substrate pad of the package substrate through a through via of the interposer.

12. The semiconductor package of claim 1, wherein:
each of the first and second semiconductor chips is a memory chip, or
the first semiconductor chip is a logic chip, and the second semiconductor chip is a memory chip.

13. A semiconductor package comprising:
a package substrate;
first and second semiconductor chips stacked on the package substrate in a stepped structure, wherein the first semiconductor chip of the first and second semiconductor chips has a first side surface and the second semiconductor chip of the first and second semiconductor chips has a second side surface;
a first side insulation layer disposed on the first and second side surfaces of the first and second semiconductor chips, the first side insulation layer having a first slope surface;
a sealant sealing the first and second semiconductor chips, on the package substrate; and
a first conductive connection pattern electrically connecting the first and second semiconductor chips to the package substrate,
wherein:
the first conductive connection pattern is in contact with the first slope surface of the first side insulation layer, the first conductive connection pattern is disposed on a portion of each of upper surfaces of the first and second semiconductor chips, and the first conductive connection pattern is disposed on a portion of an upper surface of the package substrate,
the first side insulation layer has first and second insulation patterns,
the first insulation pattern is in contact with the first side surface of the first semiconductor chip configured to have a first triangular pillar shape,
in a cross sectional view, the first triangular pillar shape has a first right-angled triangular shape,
the second insulation pattern is in contact with the second side surface of the second semiconductor chip configured to have a second triangular pillar shape,
in a cross sectional view, the second triangular pillar shape has a second right-angled triangular shape,
in the cross sectional view, each of the first and second right-angled triangular shapes have two adjacent line segments and a hypotenuse segment extending between the two adjacent line segments, the two adjacent line segments are perpendicular to each other, and the hypotenuse segment is at an acute angle to the upper surface of the package substrate,
the first and second semiconductor chips and the first and second insulation patterns are arranged such than each of the first and second side surfaces is configured to be in contact with one of a corresponding two of the adjacent line segments,
the first slope surface of the first side insulation layer includes first and second sub-surfaces each of which is configured to corresponds to one of the hypotenuse segments of the first and second right-angled triangular shapes,
the first conductive connection pattern comprises a first portion and a second portion, the first portion has a linear shape and is in contact with the first slope surface of the first side insulation layer, and the first and second portions are directly electrically connected to each other in series,
the second portion has a bent shape, and
the second portion is in contact with:
the first sub-surface of the first slope surface of the first side insulation layer and the first semiconductor chip, or
the second sub-surface of the first slope surface of the first side insulation layer and the package substrate.

14. The semiconductor package of claim 13, wherein:
the first portion formed of a first conductive material has greater electrical conductivity than the second portion, and
the second portion formed of a second conductive material has greater flexibility than the first portion.

15. The semiconductor package of claim 13, wherein:
the first side insulation layer comprises a first extension portion in contact with the upper surface of the first semiconductor chip,
the first extension portion extends from a first chip pad of the first semiconductor chip up to the first side surface of the first semiconductor chip,
the second insulation pattern comprises a second extension portion in contact with the upper surface of the second semiconductor chip,
the second extension portion extends from a second chip pad of the second semiconductor chip up to the second side surface of the of the second semiconductor chip, and
the second portion is in contact with:
the first slope surface of the first side insulation layer and the one of the first and second extension portions, such that the second portion directly electrically connects a chip pad of one of the first and second semiconductor chips to the first portion, or
the upper surface of the package substrate and one of the first and second sub-surfaces and, such that the second portion directly electrically connects a substrate pad of the package substrate to the first portion.

16. The semiconductor package of claim 13, wherein the first side insulation layer has a coefficient of thermal expansion, which is between a coefficient of thermal expansion of the sealant and a coefficient of thermal expansion of each of the first and second semiconductor chips.

17. The semiconductor package of claim 13, further comprising:
third and fourth semiconductor chips stacked on the package substrate in a stepped structure; and
an interposer disposed on the package substrate,
wherein:
the interposer is disposed at the same height level as that of the combination of the first and second semiconductor chips,
an upper one of the first and second semiconductor chips is offset laterally from a lower one of the first and second semiconductor chips in a first direction,
an upper one of the third and fourth semiconductor chips is offset laterally from a lower one of the third and fourth semiconductor chips in a second direction opposite to the first direction, and
the package substrate has a first edge and a second edge, the first direction extends from the first edge to the second edge, the first semiconductor chip is closer to the first edge than the third semiconductor chip, and the interposer is disposed closer to the second edge than the first edge.

18. A semiconductor package comprising:
a package substrate;
first and second semiconductor chips stacked on the package substrate, in a stepped configuration;
a side insulation layer disposed on a side surface of each of the first and second semiconductor chips; and
a conductive connection pattern in contact with the side insulation layer and connecting the first and second semiconductor chips to the package substrate,
wherein:
the conductive connection pattern comprises a first conductive material portion and a second conductive material portion,
the first conductive material portion has greater electrical conductivity than the second conductive material portion, and
the second conductive material portion has greater flexibility than the first conductive material portion.

19. The semiconductor package of claim 18, wherein:
the side insulation layer is in contact with the side surface of the first semiconductor chip and configured to have a triangular pillar shape,
in a cross sectional view, the side insulation layer is configured to have a right-angled triangular shape,
the side surface of the first semiconductor chip is in contact with a side surface of the side insulation layer,
the side surface of the side insulation layer is configured to correspond to a height of the right-angled triangular shape,
the side insulation layer has a slope surface, which is configured to correspond to a hypotenuse segment of the right-angled triangular shape and extends from an upper end of the side surface of the first semiconductor chip,
the hypotenuse segment has an acute angle to an upper surface of the package substrate,
the first conductive material portion is in contact with the slope surface of the side insulation layer, and
the second conductive material portion is in contact with:
the slope surface of the side insulation layer and an upper surface of the first semiconductor chip, or
the slope surface of the side insulation layer and the upper surface of the package substrate.

20. The semiconductor package of claim 18, wherein:
the second semiconductor chip is disposed closer to the package substrate than the first semiconductor chip,
the side insulation layer is in contact with and formed to extend conformally along a first upper surface of the first semiconductor chip, the side surface of the first semiconductor chip and a second upper surface of the second semiconductor chip,
the side insulation layer is formed to extend from a first chip pad of the first semiconductor chip up to a second chip pad of the second semiconductor chip,
the first conductive material portion is formed to extend along the second upper surface of the second semiconductor chip and the side surface of the first semiconductor chip,
the second conductive material portion include a first part and a second part,
the first part is formed to extend along the first upper surface of the first semiconductor chip and the first chip pad, and
the second part is formed to extend along the second upper surface of the second semiconductor chip and the second chip pad.
